(19) United States
(12) Patent Application Publication
(10) Pub. No.: US 2017/0271607 A1
(43) Pub. Date: Sep. 21, 2017

(54) DISPLAY DEVICE, DISPLAY UNIT, AND ELECTRONIC APPARATUS

(71) Applicant: JOLED Inc., Tokyo (JP)

(72) Inventor: Emiko Kambe, Tokyo (JP)

(21) Appl. No.: 15/605,036

(22) Filed: May 25, 2017

Related U.S. Application Data
(63) Continuation of application No. PCT/JP2015/065850, filed on Jun. 2, 2015.

(30) Foreign Application Priority Data
Dec. 8, 2014 (JP) 20140248014

(51) Int. Cl. H01L 51/50

(52) U.S. Cl. CPC H01L 51/504; H01L 51/5088; H01L 2251/558

(57) ABSTRACT

A display device includes an anode, a cathode, a first light emitting unit, and a second light emitting unit. The cathode faces the anode. The first light emitting unit is provided on the anode. The first light emitting unit includes at least a first light emitting layer. The second light emitting unit is provided on the cathode. The second light emitting unit includes at least a second light emitting layer. The second light emitting unit has a four-layer structure in which an acceptor layer, a donor layer, the second light emitting layer, and a mixed layer are stacked in order from the first light emitting unit. The donor layer contains one or more of aromatic tertiary amines. The mixed layer contains one or more of alkali metals and alkali earth metals and one or more of heterocyclic compounds.

### CROSS REFERENCE TO RELATED APPLICATIONS

This is a continuation of International Application No. PCT/JP2015/065850, filed Jun. 2, 2015, which claims the benefit of Japanese Priority Patent Application JP2014-248014, filed Dec. 8, 2014, the entire contents of both which are incorporated herein by reference.

### BACKGROUND

The disclosure relates to a display device that uses organic electroluminescence (EL) phenomenon to emit light, and to a display unit and an electronic apparatus each including the display device.

An organic electroluminescent device (so-called organic EL device) is a self-light-emitting device that includes, between an anode and a cathode, a light emitting layer containing an organic compound. In the organic electroluminescent device, when a voltage is applied between the anode and the cathode, holes injected from the anode move to the light emitting layer through a hole transport layer, and electrons injected from the cathode move to the light emitting layer through an electron transport layer. The holes and the electrons having moved to the light emitting layer are recombined to generate excitons, and the excitons make a transition to a ground state, thereby resulting in light emission.

In recent years, in addition to high light-emitting efficiency and long life time, high-definition light emission has been demanded for a display unit using the organic electroluminescent device as a light source. As the organic electroluminescent device with improved light-emitting efficiency, for example, Japanese Unexamined Patent Application Publication No. 2012-182126 discloses an organic electroluminescent device having a multi-stack structure (so-called tandem device). In the multi-stack structure, a plurality of light emitting units are stacked with a charge generation layer in between.

When the tandem devices are disposed adjacently to each other, a crosstalk phenomenon may occur. The crosstalk phenomenon is a phenomenon in which, when a layer having high electrical conductivity is provided in an adjacent tandem device, a current is leaked through the layer having high electrical conductivity, and the tandem device adjacent to a specified tandem device also emits light. Typically, a plurality of layers each including the light emitting layer are stacked with a middle layer having high electrical conductivity in between in the tandem device. The tandem device has electric resistance between the anode and the cathode higher than the electric resistance of a so-called single device that has one light emitting unit between the electrodes. Therefore, in the tandem device, the current is easily leaked to an adjacent pixel through the middle layer having high electrical conductivity.

Therefore, as a technology to suppress occurrence of the crosstalk, for example, Japanese Unexamined Patent Application Publications No. 2014-123527 and No. 2014-82133 each disclose a light emitting unit in which a recess or a protrusion is provided on a partition wall between the tandem devices adjacent to each other. In addition, Japanese Unexamined Patent Application Publication No. 2012-155953 discloses an organic EL display unit in which a metal wiring line electrically coupled to an organic layer is provided around an anode electrode.

### SUMMARY

Providing a structural object between pixels as in Japanese Unexamined Patent Application Publications No. 2014-123527, No. 2014-82133, and No. 2012-155953, however, inhibits high definition. In a high definition display, a pixel layout is limited. Therefore, adding the wiring lines makes it difficult to arrange the pixels, and adding the structural object on the partition wall decreases a pixel opening, which reduces lifetime of the display because high current density is necessary for equivalent luminance.

It is desirable to provide a display device, a display unit, and an electronic apparatus that have high definition and high light-emitting efficiency while suppressing a crosstalk phenomenon.

A display device according to an embodiment of the technology includes an anode, a cathode, a first light emitting unit, and a second light emitting unit. The cathode faces the anode. The first light emitting unit is provided on the anode. The first light emitting unit includes at least a first light emitting layer. The second light emitting unit is provided on the cathode. The second light emitting unit includes at least a second light emitting layer. The second light emitting unit has a four-layer structure in which an acceptor layer, a donor layer, the second light emitting layer, and a mixed layer are stacked in order from the first light emitting unit. The donor layer contains one or more of aromatic tertiary amines. The mixed layer contains one or more of alkali metals and alkali earth metals and one or more of heterocyclic compounds.

A display unit according to an embodiment of the technology is provided with a plurality of display devices. Each of the display devices includes an anode, a cathode, a first light emitting unit, and a second light emitting unit. The cathode faces the anode. The first light emitting unit is provided on the anode. The first light emitting unit includes at least a first light emitting layer. The second light emitting unit is provided on the cathode. The second light emitting unit includes at least a second light emitting layer. The second light emitting unit has a four-layer structure in which an acceptor layer, a donor layer, the second light emitting layer, and a mixed layer are stacked in order from the first light emitting unit. The donor layer contains one or more of aromatic tertiary amines. The mixed layer contains one or more of alkali metals and alkali earth metals and one or more of heterocyclic compounds.

An electronic apparatus according to an embodiment of the technology is provided with a display unit. The display unit includes a plurality of display devices in a display section. Each of the display devices includes an anode, a cathode, a first light emitting unit, and a second light emitting unit. The cathode faces the anode. The first light emitting unit is provided on the anode. The first light emitting unit includes at least a first light emitting layer. The second light emitting unit is provided on the cathode. The second light emitting unit includes at least a second light emitting layer. The second light emitting unit has a four-layer structure in which an acceptor layer, a donor layer, the second light emitting layer, and a mixed layer are stacked in order from the first light emitting unit. The donor layer contains one or more of aromatic tertiary amines. The mixed layer contains one or more of alkali metals and alkali earth metals and one or more of heterocyclic compounds.

### BRIEF DESCRIPTION OF THE DRAWINGS

The accompanying drawings are included to provide a further understanding of the disclosure, and are incorporated in and constitute a part of this specification. The drawings illustrate embodiments and, together with the specification, serve to explain the principles of the technology.

FIG. 1 is a cross-sectional view of a display device according to an embodiment of the disclosure.

FIG. 2 is a plan view of a configuration of a display unit including the display device illustrated in FIG. 1.

FIG. 3 illustrates an example of a pixel drive circuit of the display unit illustrated in FIG. 2.

FIG. 4 illustrates an example of a cross-sectional configuration of the display unit illustrated in FIG. 2.

FIG. 5 is a plan view of a schematic configuration of a module including the above-described display unit.

FIG. 6A is a perspective view of an appearance of Application Example 1 of the above-described display unit as viewed from a front side thereof.

FIG. 6B is a perspective view of the appearance of Application Example 1 illustrated in FIG. 6A as viewed from a rear side thereof.

FIG. 7A is a perspective view of an example of an appearance of Application Example 2 of the above-described display unit.

FIG. 7B is a perspective view of another example of the appearance of Application Example 2 of the above-described display unit.

### DETAILED DESCRIPTION

Some embodiments of the technology are described in detail, in the following order, with reference to the accompanying drawings.

1. Embodiment (an example of providing, on cathode side, a second light emitting unit that includes an acceptor layer, a donor layer, a light emitting layer, and a mixed layer)

1-1. Configuration of Key Part

1-2. Entire Configuration

1-3. Workings and Effects

### 2. Application Examples

### 3. Examples

### 1. Embodiment

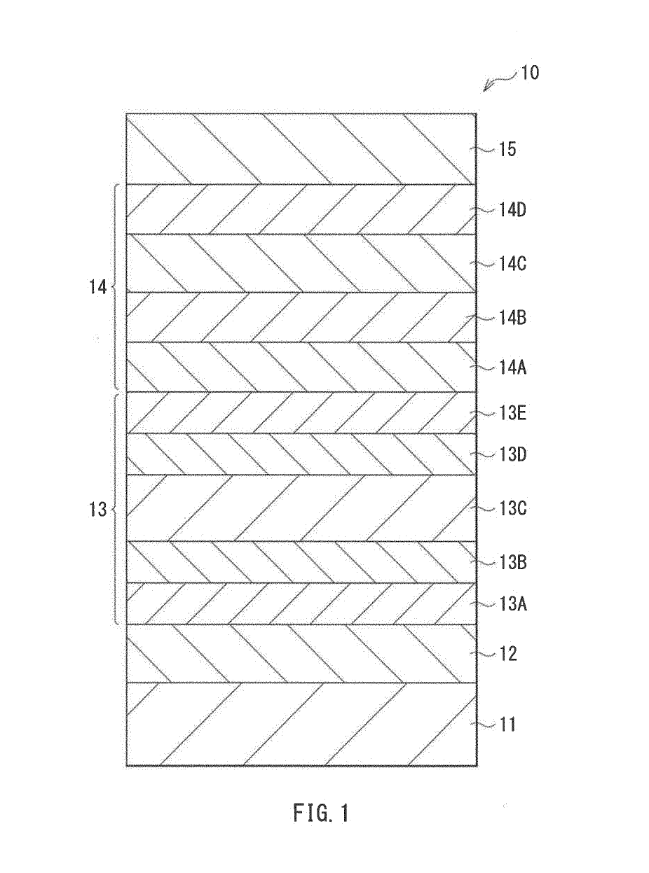

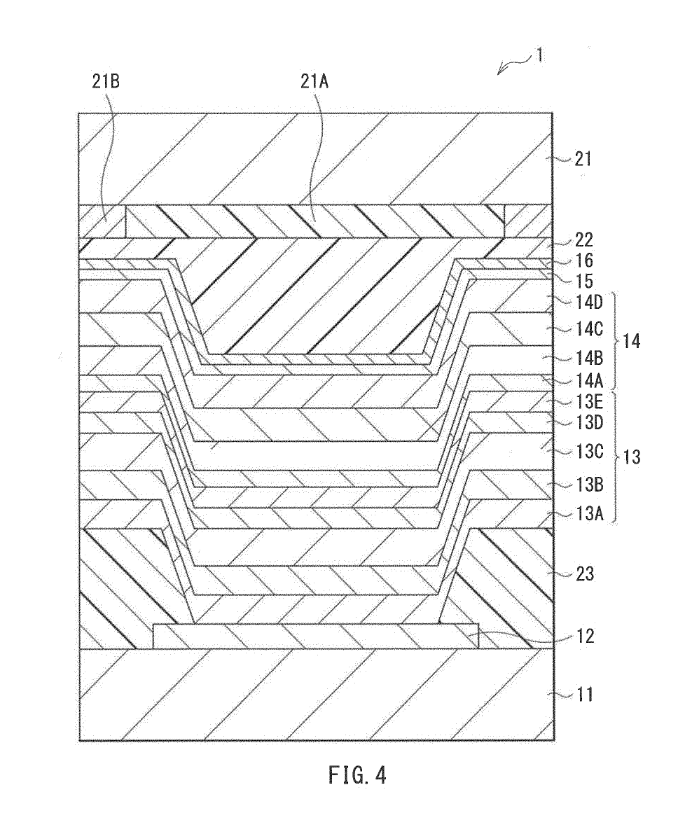

FIG. 1 illustrates a cross-sectional configuration of a display device (a display device 10) according to an embodiment of the disclosure. The display device 10 may be used as, for example, a display device of a mobile terminal apparatus such as a tablet and a smartphone. The display device 10 may have a so-called tandem structure in which an anode 12, a first light emitting unit 13, a second light emitting unit 14, and a cathode 15 are stacked in this order on a drive substrate 11. The display device 10 may be a top surface emission (so-called top emission) organic electroluminescent device in which light emitted at a time when holes injected from the anode 12 and electrons injected from the cathode 15 are recombined in a light emitting layer 13C provided in the first light emitting unit 13 and in a light emitting layer 14C provided in the second light emitting unit 14, is extracted from side opposite to the drive substrate 11 (counter substrate 21 side, see FIG. 4).

### [1-1. Structure of Key Part]

In the display device 10 according to the present embodiment, the second light emitting unit 14 may have a four-layer structure in which an acceptor layer 14A, a donor layer 14B, the light emitting layer 14C, and a mixed layer 14D are stacked in this order from the anode 12.

The acceptor layer 14A may supply charges to both of the first light emitting unit 13 and the second light emitting unit 14, and may be preferably made of a material having an acceptor property, for example, hexaazatriphenylene represented by the following formula (1) and a derivative thereof. Note that R of hexaazatriphenylene represented by the formula (1) may be preferably a cyano group. In addition, for example, any of a fluorinated derivative of cyano benzoquinone dimethane and a p-type acceptor material may be used. Specific but non-limiting examples of the fluorinated derivative of cyano benzoquinone dimethane may include compounds described in European Patent No. 1912268 and U.S. Patent Application Publication No. 2006/0250076. Specific but non-limiting examples of the p-type acceptor material may include radialenes, as represented by the formulae (2-1) to (2-3), described in U.S. Patent Application Publication No. 2008/0265216; Iyoda et al., Organic Letters, 6(25), 4667-4670 (2004); Japanese Patent No. 3960131; Enomoto et al., Bull. Chem. Soc. Jap., 73(9), 2109-2114 (2000); Enomoto et al., Tet. Let., 38(15), 2693-2696 (1997); and Iyoda et al., JCS, Chem. Comm., (21), 1690-1692 (1989).

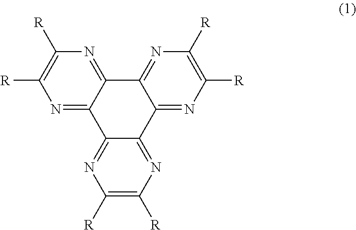

(R is independently a substituent selected from the group consisting of a hydrogen atom, a halogen atom, a hydroxyl group, an amino group, an arylamino group, a carbonyl group having 20 or less carbon atoms, a carbonyl ester group having 20 or less carbon atoms, an alkyl group having 20 or less carbon atoms, an alkenyl group having 20 or less carbon atoms, an alkoxyl group having 20 or less carbon atoms, an aryl group having 30 or less carbon atoms, a heterocyclic group having 30 or less carbon atoms, a nitrile group, a cyano group, a nitro group, and a silyl group, or a derivative thereof.)

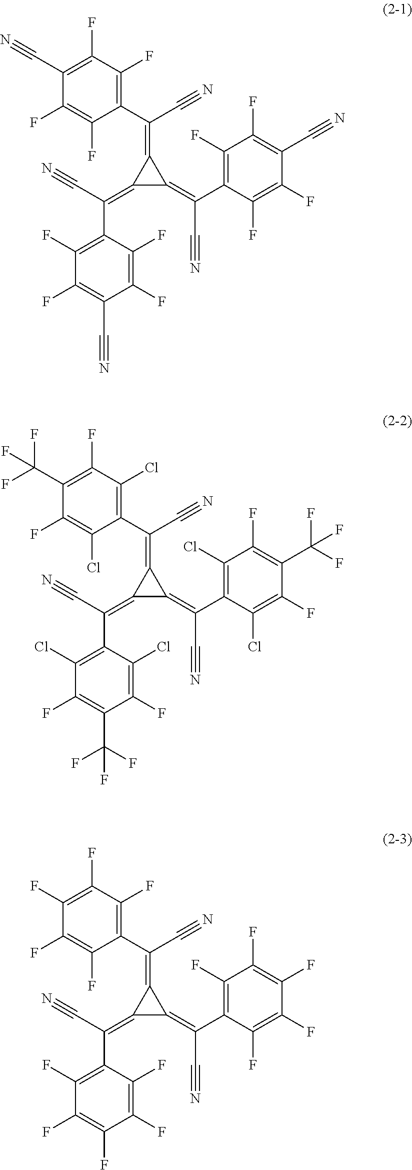 [SMILES: N#CC(=C1C(=C(C#N)c2c(F)c(F)c(C#N)c(F)c2F)C1=C(C#N)c1c(F)c(F)c(C#N)c(F)c1F)c1c(F)c(F)c(C#N)c(F)c1F ; N#CC(=C1C(=C(C#N)c2c(Cl)c(F)c(C(F)(F)F)c(F)c2Cl)C1=C(C#N)c1c(Cl)c(F)c(C(F)(F)F)c(F)c1Cl)c1c(Cl)c(F)c(C(F)(F)F)c(F)c1Cl ; N#CC(=C1C(=C(C#N)c2c(F)c(F)c(F)c(F)c2F)C1=C(C#N)c1c(F)c(F)c(F)c(F)c1F)c1c(F)c(F)c(F)c(F)c1F]

The donor layer 14B may be provided to transport, to the light emitting layer 14C, holes supplied from the acceptor layer 14A. The donor layer 14B may be preferably made of a compound having a hole transport property with large triplet excitation (T1) energy, in consideration of confining of excitons in the light emitting layer. Specific but non-limiting example of the compound may include an aromatic tertiary amine compound having a hole transport property, as represented by the formulae (3-1) to (3-10). The acceptor layer 14A may preferably have a thickness in a range, for example, from 5 nm to 40 nm, depending on the entire configuration of the display device 10.

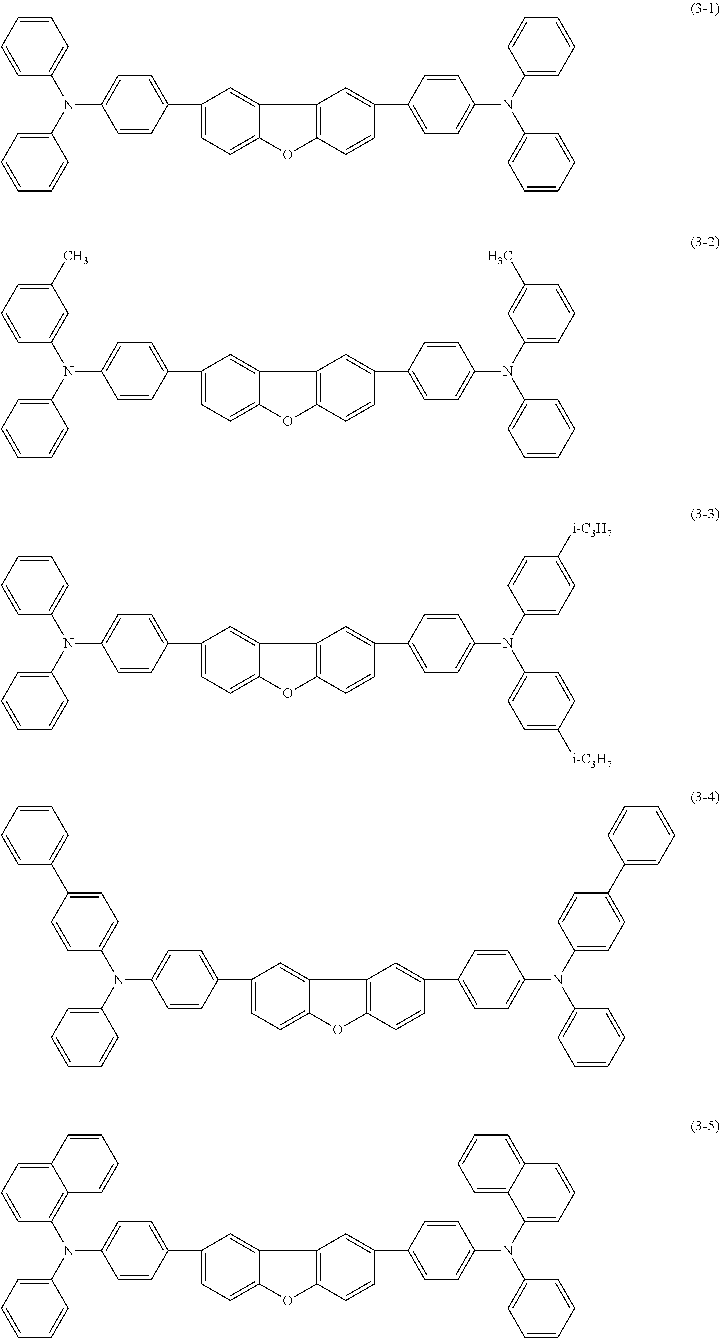

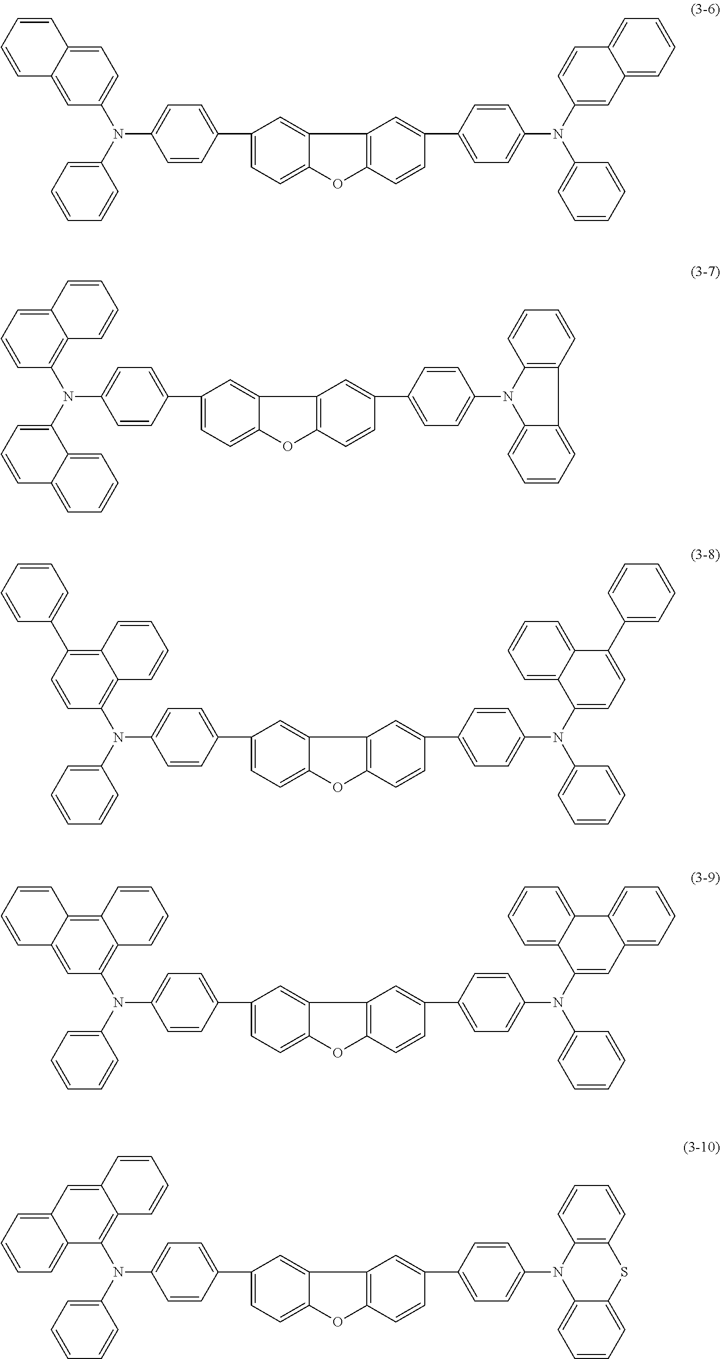

The light emitting layer 14C may receive holes from the anode 12 (more specifically, from the acceptor layer 14A) through the donor layer 14B and receive electrons from the cathode 15 through the mixed layer 14D, upon application of an electric field. The received holes and electrons may be recombined in the light emitting layer 14C. The light emitting layer 14C may preferably contain one or more of light emitting dopants and a host material.

As the light emitting dopant, for example, a phosphorescent dopant that provides light (phosphorescence) emitted from triplet excitons may be preferably used. Examples of the phosphorescent dopant may include a complex containing a transition metal atom or a lanthanoid atom. Examples of the transition metal atom may include ruthenium (Ru), rhodium (Rh), palladium (Pd), tungsten (W), rhenium (Re), osmium (Os), iridium (Ir), and platinum (Pt). The transition metal atom may be more preferably Re, Ir, and Pt, and still more preferably Ir and Pt. Examples of the lanthanoid atom may include lanthanum (La), cerium (Ce), praseodymium (Pr), neodymium (Nd), samarium (Sm), europium (Eu), gadolinium (Gd), terbium (Tb), dysprosium (Dy), holmium (Ho), erbium (Er), thulium (Tm), ytterbium (Yb), and lutetium (Lu). Among the lanthanoid atoms, Nd, Eu, and Gd may be preferable.

Examples of a complex ligand may include a halogen ligand (preferably, a chlorine ligand), an aromatic carbocyclic ligand (for example, cyclopentadienyl anion, benzene anion, and naphthyl anion), a nitrogen-containing heterocyclic ligand (for example, phenylpyridine, benzoquinoline, quinolinol, bipyridyl, and phenanthroline), a carbene ligand, a diketone ligand (for example, acetylacetone), a carboxylic acid ligand (for example, an acetic acid ligand), an alcoholate ligand (for example, a phenolate ligand), a carbon monoxide ligand, an isonitrile ligand, and a cyano ligand. More preferably, the complex ligand may be a nitrogen-containing heterocyclic ligand. The above-described complex may contain one transition metal atom in the compound, or may be so-called dinuclear complex that contains two or more transition metal atoms in the compound. The above-described complex may contain different metal atoms together.

Note that, as the light emitting dopant, a fluorescent dopant may be used besides a phosphorescent dopant. Examples of the fluorescent material may include a benzoxazole derivative, a benzoimidazole derivative, a benzothiazole derivative, a styrylbenzene derivative, a polyphenyl derivative, a diphenylbutadiene derivative, a tetraphenyl butadiene derivative, a naphthalimide derivative, a coumarin derivative, a perylene derivative, a perinone derivative, an oxadiazole derivative, an aldazine derivative, a pyrralidine derivative, a cyclopentadiene derivative, a bisstylylanthracene derivative, a quinacridone derivative, a pyrrolopyridine derivative, a thiadiazolopyridine derivative, a styrylamine derivative, an aromatic dimethylidene derivative, various metal complexes typified by a metal complex of a 8-quinolinol derivative or a rare earth metal complex, and polymer compounds such as a polythiophene derivative, a polyphenylene derivative, a polyphenylenevinylene derivative, and a polyfluorene derivative. One or two or more thereof may be mixed and used.

An amount of the light emitting dopants contained in the light emitting layer 14C may be in a range, for example, from 0.1 mass % to 30 mass % with respect to total amount of the compounds that form the light emitting layer 14C; however, the amount may be preferably in a range from 2 mass % to 30 mass %, and more preferably in a range from 5 mass % to 30 mass %, in terms of durability and external quantum efficiency.

As the host material, a hole transporting material excellent in a hole transport property and an electron transporting material excellent in an electron transport property.

The hole transporting material may preferably have an ionization potential Ip in a range from 5.1 eV to 6.4 eV, more preferably from 5.4 eV to 6.2 eV, and still more preferably 5.6 eV to 6.0 eV, in terms of improvement in durability and reduction in a drive voltage. In addition, the hole transporting material may preferably have an electron affinity Ea in a range from 1.2 eV to 3.1 eV, more preferably 1.4 eV to 3.0 eV, and still more preferably 1.8 eV to 2.8 eV, in terms of improvement in durability and reduction in the drive voltage.

Examples of such a hole transporting material may include pyrrole, carbazole, azacarbazole, indole, azaindole, pyrazole, imidazole, polyarylalkane, pyrazoline, pyrazolone, phenylenediamine, arylamine, amino-substituted chalcone, styryl anthracene, fluorenone, hydorazone, stilbene, silazane, an aromatic tertiary amine compound, a styryl amine compound, an aromatic dimethylidene compound, a porphyrin compound, a polysilane compound, poly(N-vinylcarbazole), an aniline copolymer, an electrically conductive high molecular oligomer such as thiophene oligomer and polythiophene, an organic silane, a carbon film, and a derivative thereof. Among them, an indole derivative, a carbazole derivative, an azaindole derivative, an azacarbazole derivative, an aromatic tertiary amine compound, and a thiophene derivative may be preferable, and in particular, a material that contains a plurality of carbazole skeletons and/or indole skeletons and/or aromatic tertiary amine skeletons in a molecule may be preferable. More specifically, for example, the compounds represented by the following formulae (4-1) to (4-26) may be preferable without limitation.

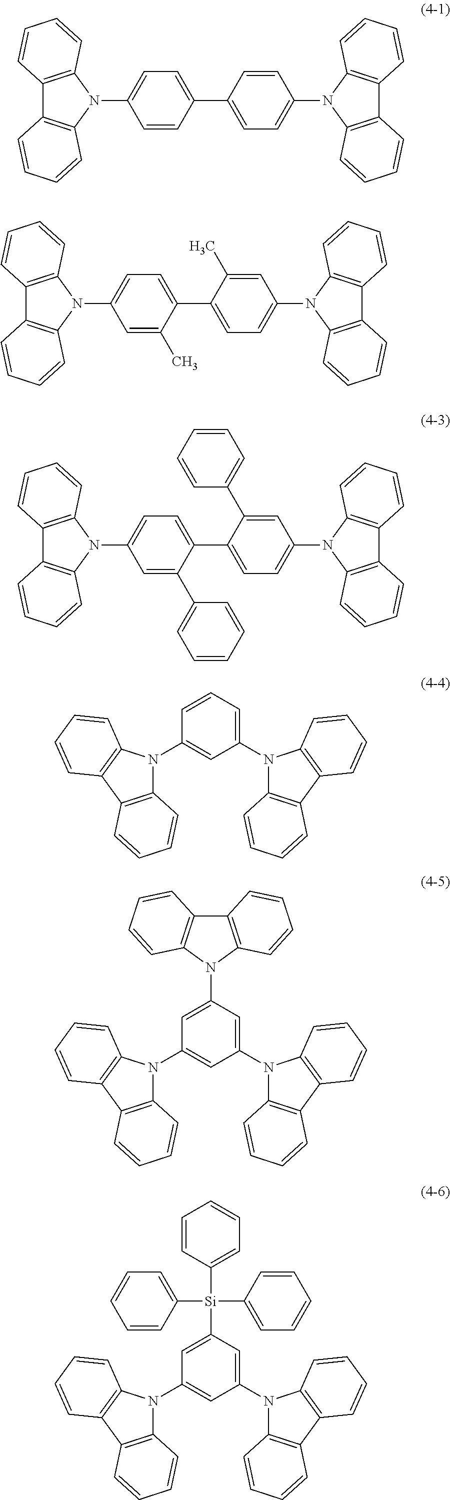

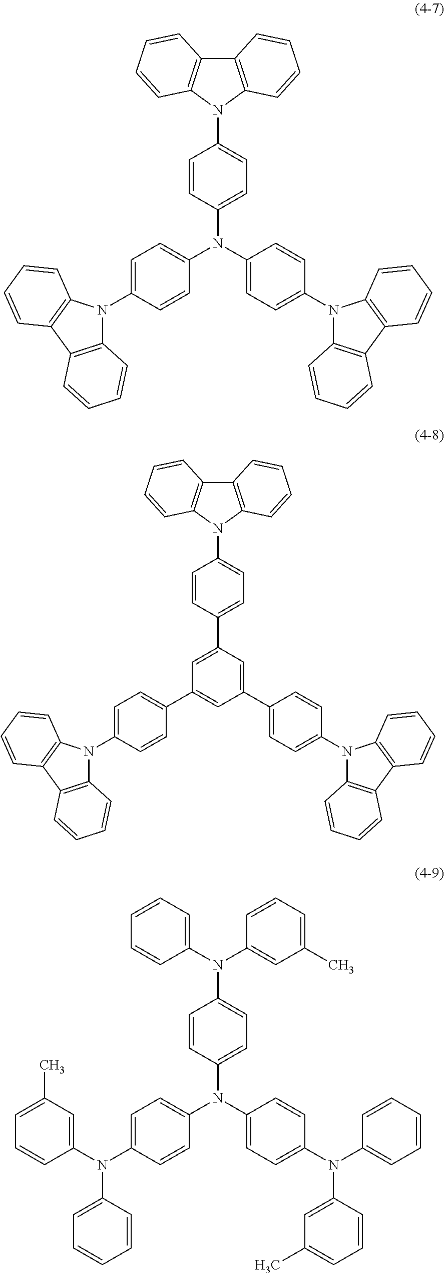 [SMILES: c1ccc2c(c1)c1ccccc1n2-c1ccc(N(c2ccc(-n3c4ccccc4c4ccccc43)cc2)c2ccc(-n3c4ccccc4c4ccccc43)cc2)cc1 ; c1ccc2c(c1)c1ccccc1n2-c1ccc(-c2cc(-c3ccc(-n4c5ccccc5c5ccccc54)cc3)cc(-c3ccc(-n4c5ccccc5c5ccccc54)cc3)c2)cc1 ; Cc1cccc(N(c2ccccc2)c2ccc(N(c3ccc(N(c4ccccc4)c4cccc(C)c4)cc3)c3ccc(N(c4ccccc4)c4cccc(C)c4)cc3)cc2)c1]

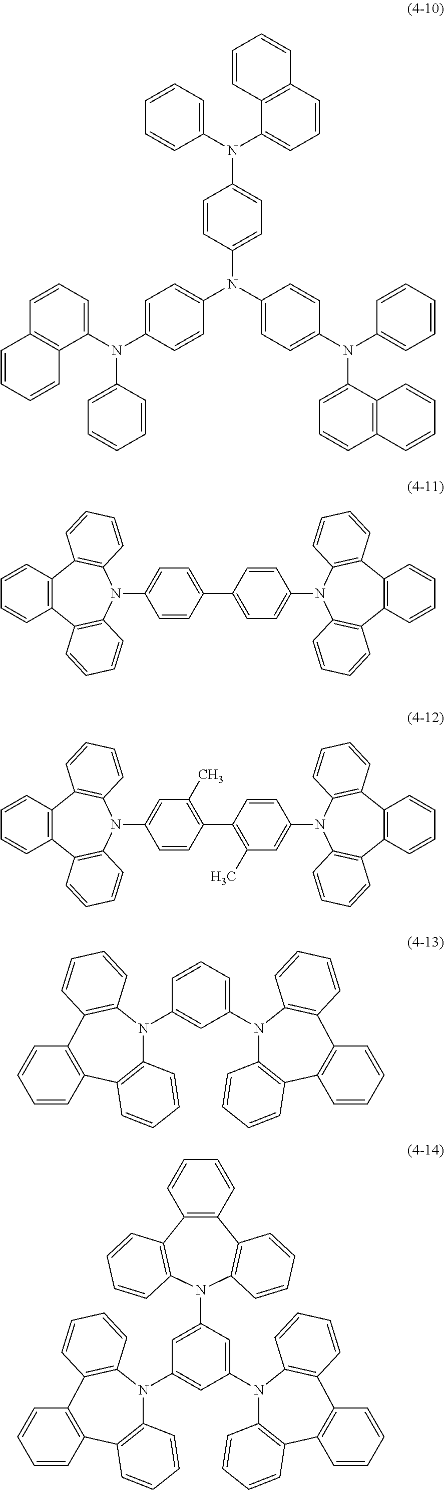

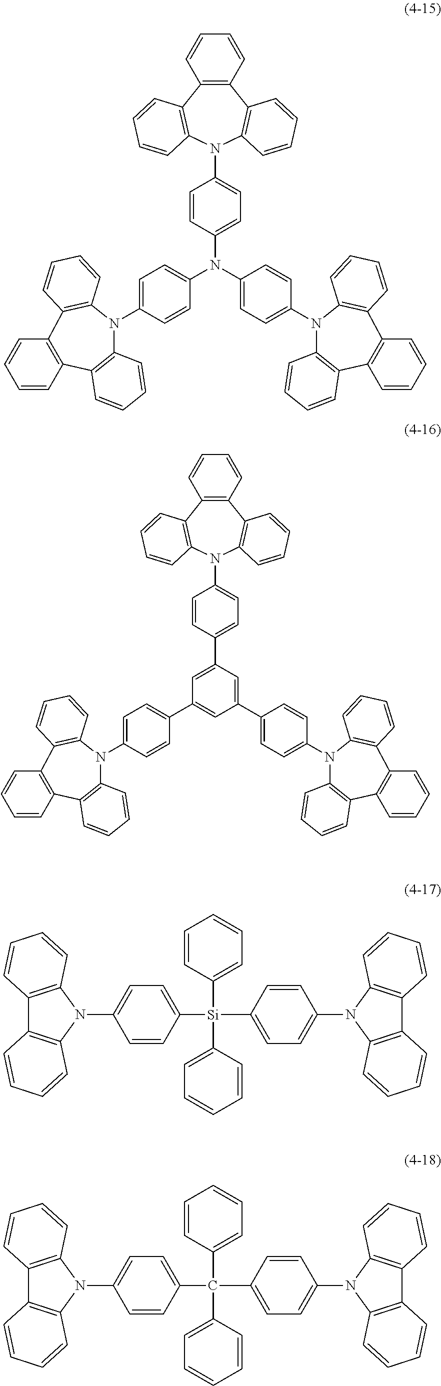 [SMILES: c1ccc2c(c1)-c1ccccc1N(c1ccc(N(c3ccc(N4c5ccccc5-c5ccccc5-c5ccccc54)cc3)c3ccc(N4c5ccccc5-c5ccccc5-c5ccccc54)cc3)cc1)c1ccccc1-2 ; c1ccc2c(c1)-c1ccccc1N(c1ccc(-c3cc(-c4ccc(N5c6ccccc6-c6ccccc6-c6ccccc65)cc4)cc(-c4ccc(N5c6ccccc6-c6ccccc6-c6ccccc65)cc4)c3)cc1)c1ccccc1-2 ; c1ccc([Si](c2ccccc2)(c2ccc(-n3c4ccccc4c4ccccc43)cc2)c2ccc(-n3c4ccccc4c4ccccc43)cc2)cc1 ; c1ccc(C(c2ccccc2)(c2ccc(-n3c4ccccc4c4ccccc43)cc2)c2ccc(-n3c4ccccc4c4ccccc43)cc2)cc1]

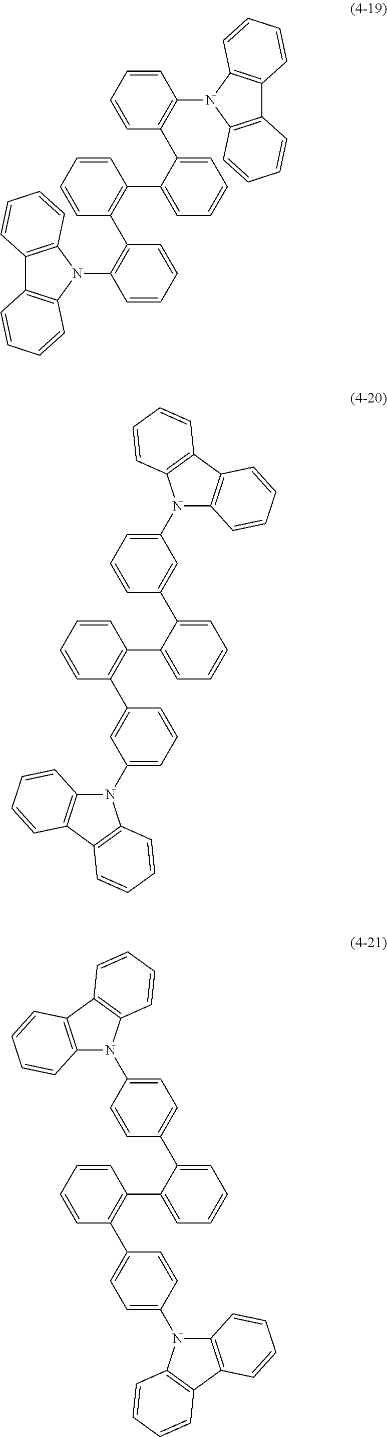 [SMILES: c1ccc(-c2ccccc2-n2c3ccccc3c3ccccc32)c(-c2ccccc2-c2ccccc2-n2c3ccccc3c3ccccc32)c1 ; c1cc(-c2ccccc2-c2ccccc2-c2cccc(-n3c4ccccc4c4ccccc43)c2)cc(-n2c3ccccc3c3ccccc32)c1 ; c1ccc(-c2ccccc2-c2ccc(-n3c4ccccc4c4ccccc43)cc2)c(-c2ccc(-n3c4ccccc4c4ccccc43)cc2)c1]

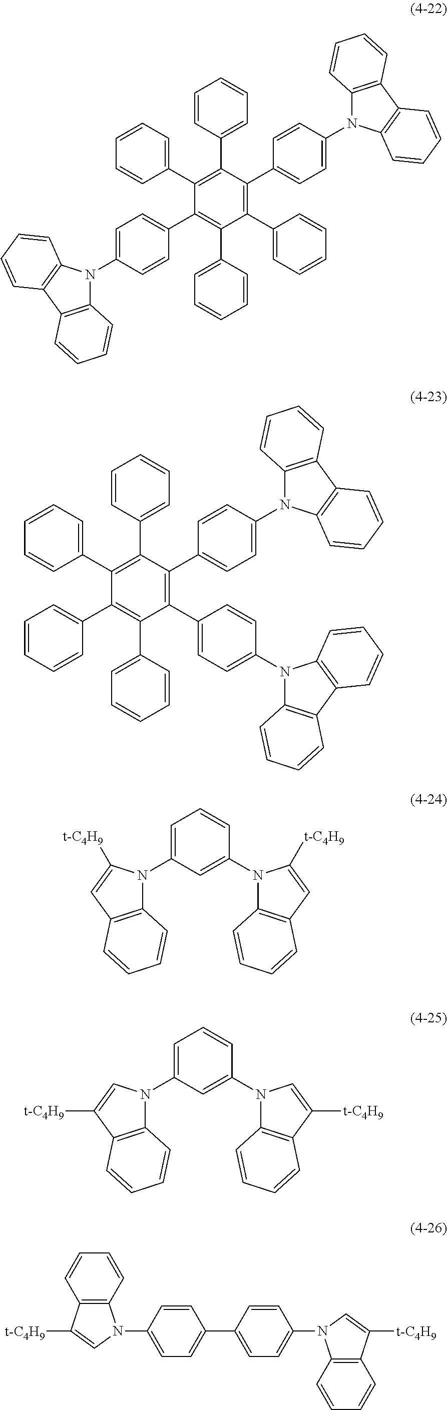

The electron transporting material may preferably have an electron affinity Ea in a range from 2.5 eV to 3.5 eV, more preferably 2.6 eV to 3.4 eV, and still more preferably 2.8 eV to 3.3 eV, in terms of improvement in durability and reduction in the drive voltage. In addition, the electron transporting material may preferably have an ionization potential Ip in a range from 5.7 eV to 7.5 eV, more preferably 5.8 eV to 7.0 eV, and still more preferably 5.9 eV to 6.5 eV, in terms of improvement in durability and reduction in the drive voltage.

Examples of such an electron transporting material may include pyridine, pyrimidine, triazine, imidazole, pyrazole, triazole, oxazole, oxadiazole, fluorenone, anthraquinodimethane, anthrone, diphenylquinone, thiopyrandioxide, carbodiimide, fluorenylidenemethane, distyrylpyrazine, a fluorine-substituted aromatic compound, a heterocyclic tetracarboxylic acid anhydride such as naphthalene and perylene, phthalocyanine and a derivative thereof (may form a condensed ring with another ring), and various metal complexes typified by a metal complex of a 8-quinolinol derivative, metal phthalocyanine, and a metal complex with benzoxazole or benzothiazole as a ligand.

Preferable examples of the electron transporting host may include a metal complex, an azole derivative (such as a benzimidazole derivative and an imidazopyridine derivative), an azine derivative (such as a pyridine derivative, a pyrimidine derivative, and a triazine derivative).

Examples of the metal complex electron transporting host may include compounds described in, for example, Japanese Unexamined Patent Application Publications No. 2004-214179, No. 2004-221062, No. 2004-221065, No. 2004-221068, and No. 2004-327313. Specific but non-limiting examples of the metal complex electron transporting host may include compounds represented by the following formulae (5-1) to (5-26).

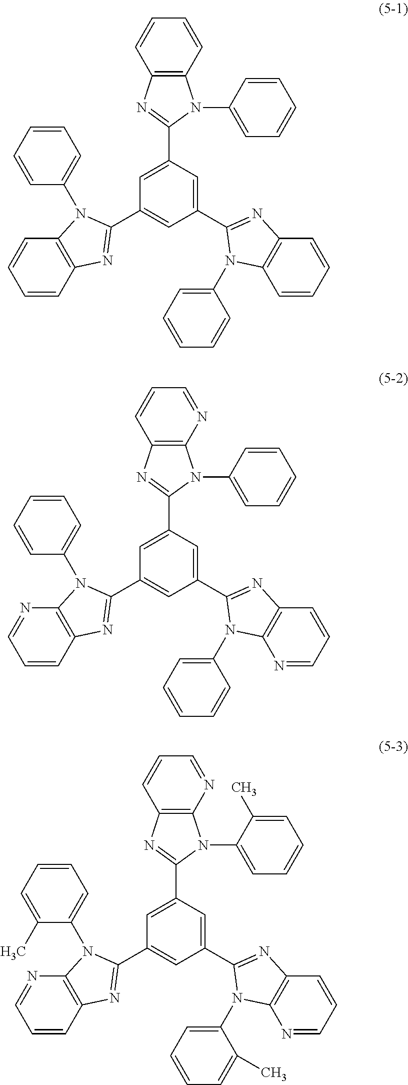

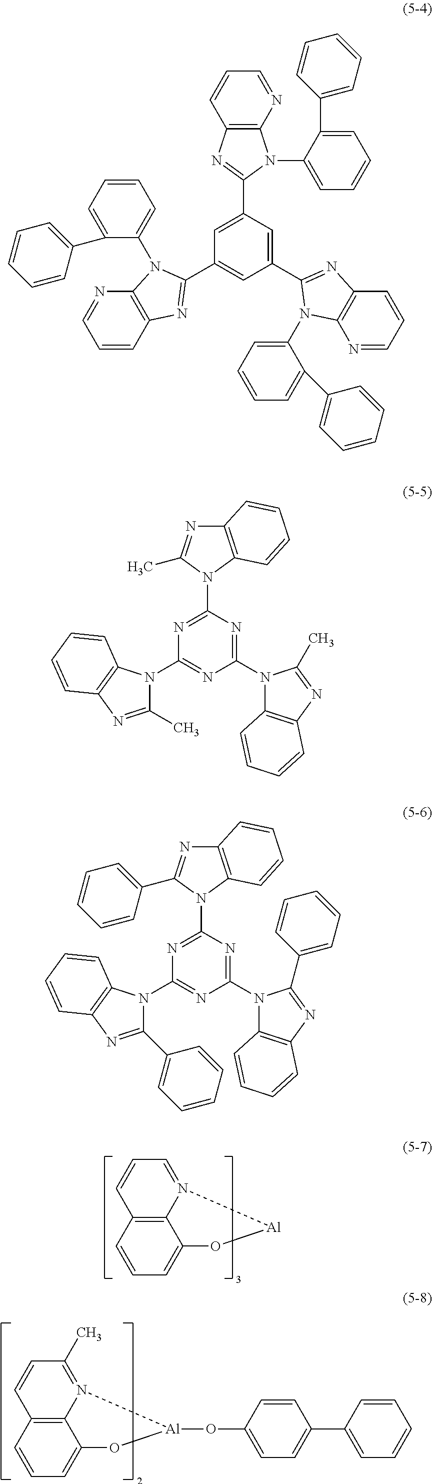

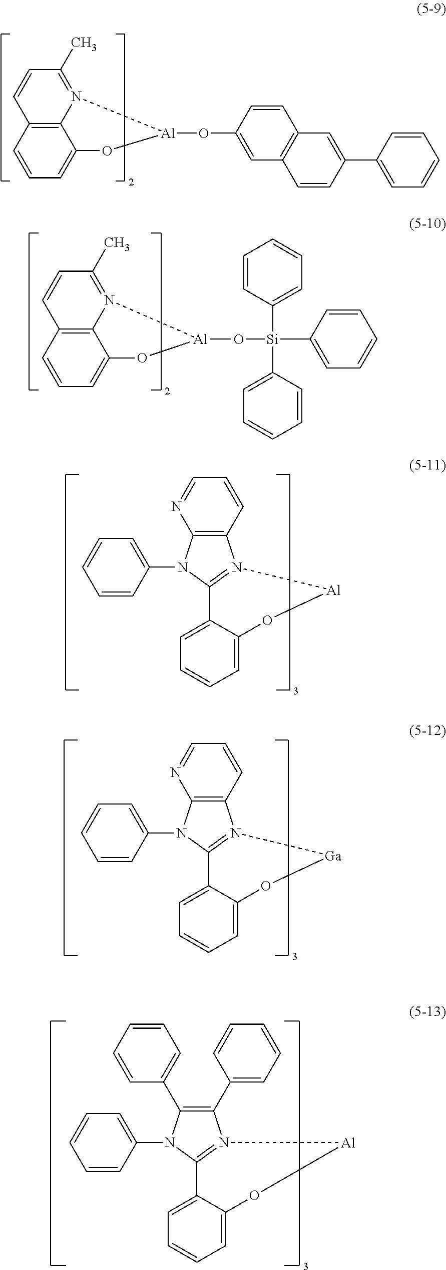

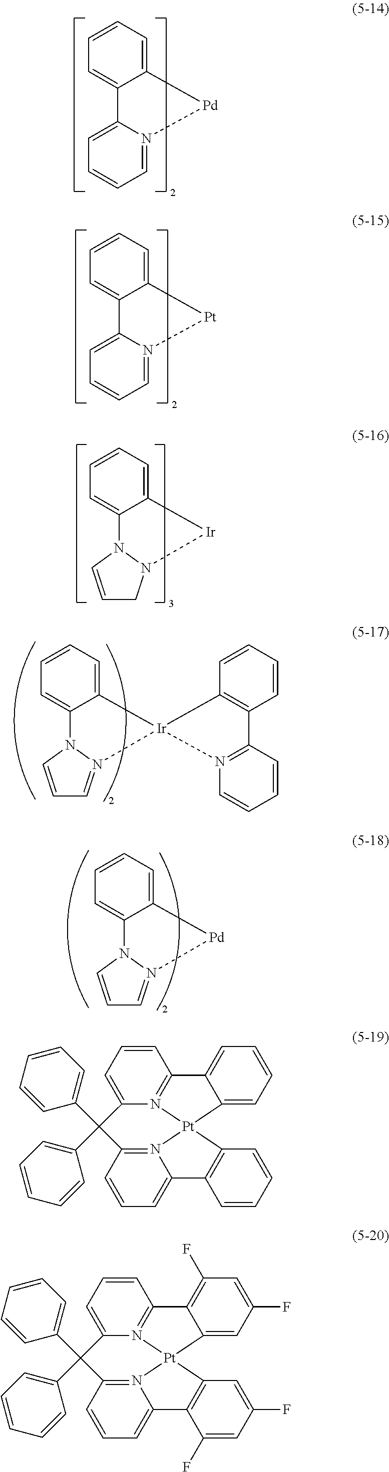

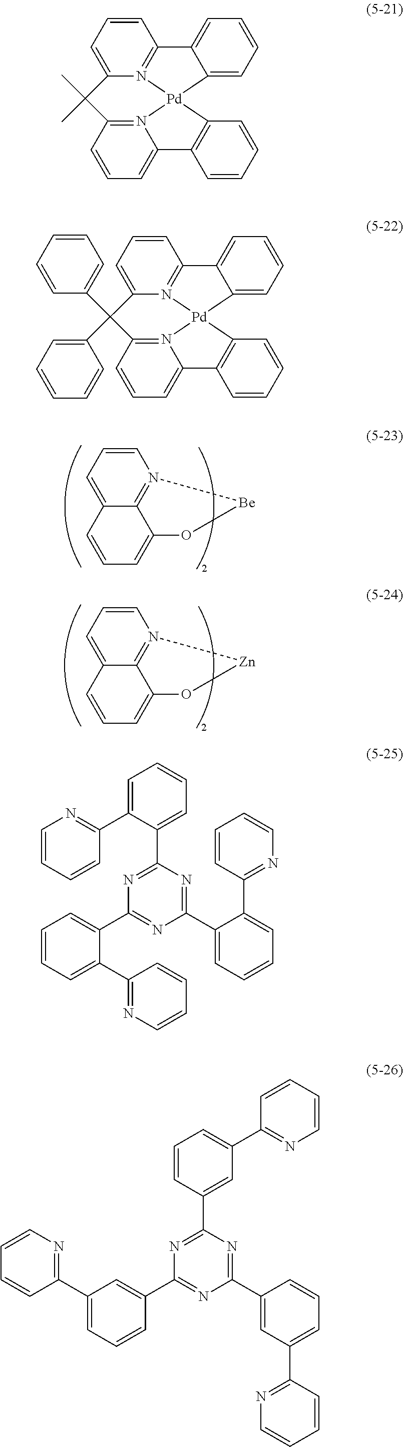

For example, as illustrated in FIG. 1, the light emitting layer 14C may be a monolayer that emits red light, green light, blue light, yellow light, or other light. Alternatively, the light emitting layer 14C may also be configured by stacking a plurality of light emitting layers (for example, a red light emitting layer and a green light emitting layer) each of which emits different color light. The light emitting layer 14C may preferably have a thickness in a range, for example, from 5 nm to 30 nm, and more preferably from 10 nm to 20 nm, depending on the entire configuration of the display device 10. Note that the host material of the light emitting layer may be often lower in a charge transport capacity than the hole transport layer (the hole transport layer 13B) or the mixed layer (the mixed layer 14D) which are described later. Therefore, providing the thick light emitting layer in the second light emitting unit 14 may cause current leakage. Accordingly, a mixed-host light emitting layer may be preferably used in order to maintain high efficiency with a thin film. This makes it possible to improve charge balance even when the film is thin.

The mixed layer 14D may be provided to transport, to the light emitting layer 14C, electrons injected from the cathode 15. The mixed layer 14D may preferably contain, for example, one or more guest materials and a host material. As the guest materials, an alkali metal such as lithium (Li), sodium (Na), and potassium (K), or an alkali earth metal such as beryllium (Be), magnesium (Mg), and calcium (Ca) may be preferably used. As the host material, one or more of heterocyclic compounds may be preferably used, and specific but non-limiting examples thereof may include compounds represented by the following formulae (6-1) to (6-14).

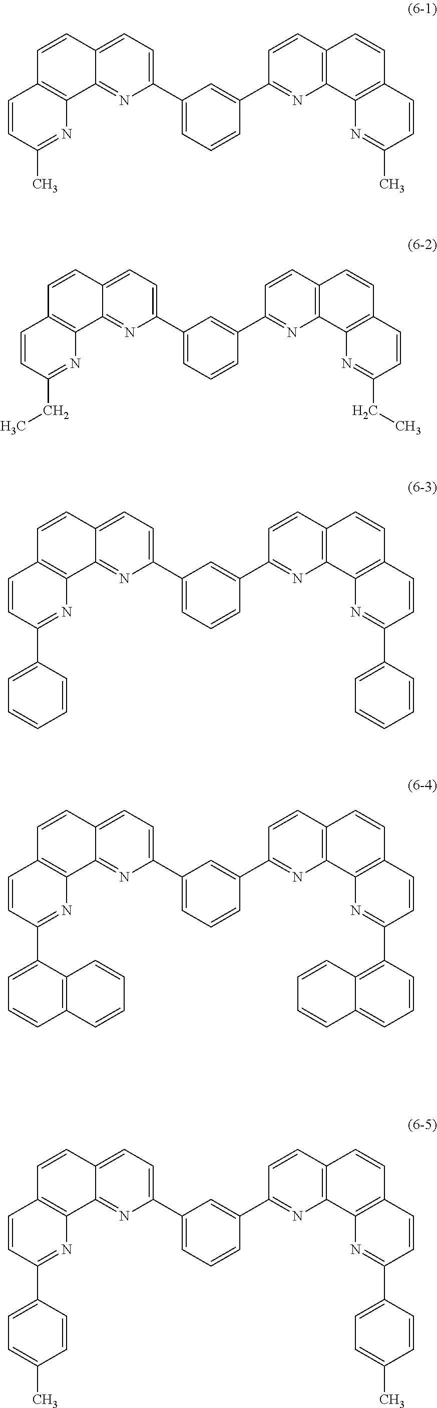 [SMILES: Cc1ccc2ccc3ccc(-c4cccc(-c5ccc6ccc7ccc(C)nc7c6n5)c4)nc3c2n1 ; CCc1ccc2ccc3ccc(-c4cccc(-c5ccc6ccc7ccc(CC)nc7c6n5)c4)nc3c2n1 ; c1ccc(-c2ccc3ccc4ccc(-c5cccc(-c6ccc7ccc8ccc(-c9ccccc9)nc8c7n6)c5)nc4c3n2)cc1 ; c1cc(-c2ccc3ccc4ccc(-c5cccc6ccccc56)nc4c3n2)cc(-c2ccc3ccc4ccc(-c5cccc6ccccc56)nc4c3n2)c1 ; Cc1ccc(-c2ccc3ccc4ccc(-c5cccc(-c6ccc7ccc8ccc(-c9ccc(C)cc9)nc8c7n6)c5)nc4c3n2)cc1]

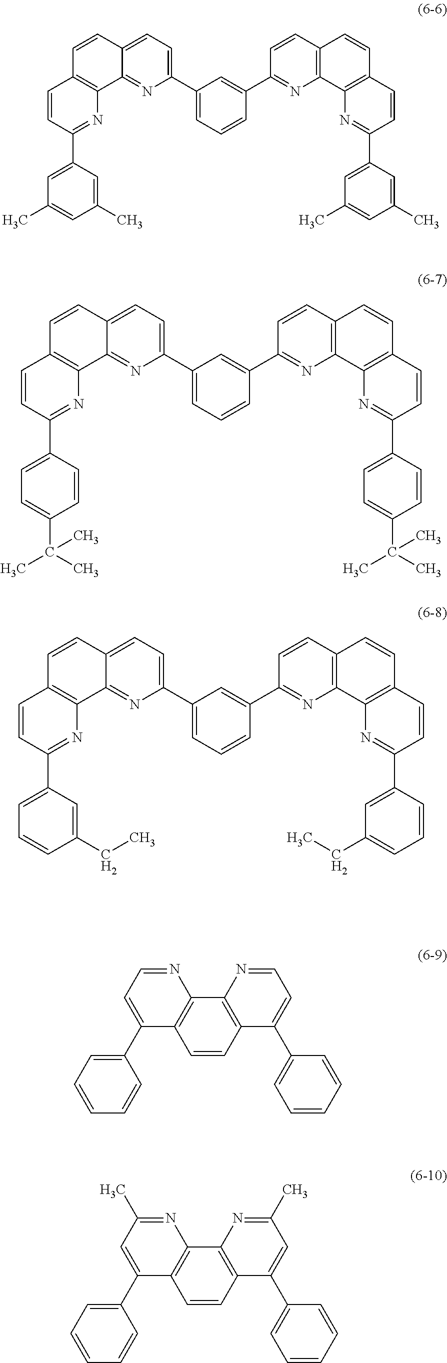

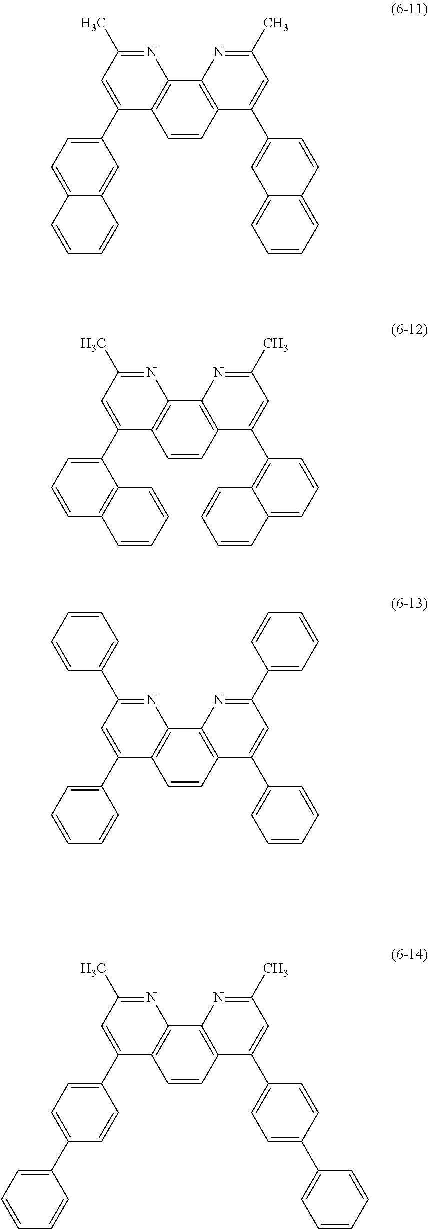 [SMILES: Cc1cc(-c2ccc3ccccc3c2)c2ccc3c(-c4ccc5ccccc5c4)cc(C)nc3c2n1 ; Cc1cc(-c2cccc3ccccc23)c2ccc3c(-c4cccc5ccccc45)cc(C)nc3c2n1 ; c1ccc(-c2cc(-c3ccccc3)c3ccc4c(-c5ccccc5)cc(-c5ccccc5)nc4c3n2)cc1 ; Cc1cc(-c2ccc(-c3ccccc3)cc2)c2ccc3c(-c4ccc(-c5ccccc5)cc4)cc(C)nc3c2n1]

The mixed layer 14D may preferably have a film thickness in a range, for example, from 5 nm to 200 nm, and more preferably from 10 nm to 150 nm, depending on the entire configuration of the display device 10.

As described above, in the display device 10 according to the present embodiment, the first light emitting unit 13 and the second light emitting unit 14 are stacked between the anode 12 and the cathode 15 in order from the anode 12. The second light emitting unit 14, among them, which is not in direct contact with the anode 12 has the above-described four-layer structure. This improves the efficiency of injecting holes from the acceptor layer 14A and the donor layer 14B to the light emitting layer 14C and the efficiency of injecting electrons from the cathode 15 and the mixed layer 14D to the light emitting layer 14C, thereby reducing inflow (leakage) of charges into an adjacent display device.

The entire configuration of a display unit (a display unit 1) including the first light emitting unit 13 is described below.

### [1-2. Entire Configuration]

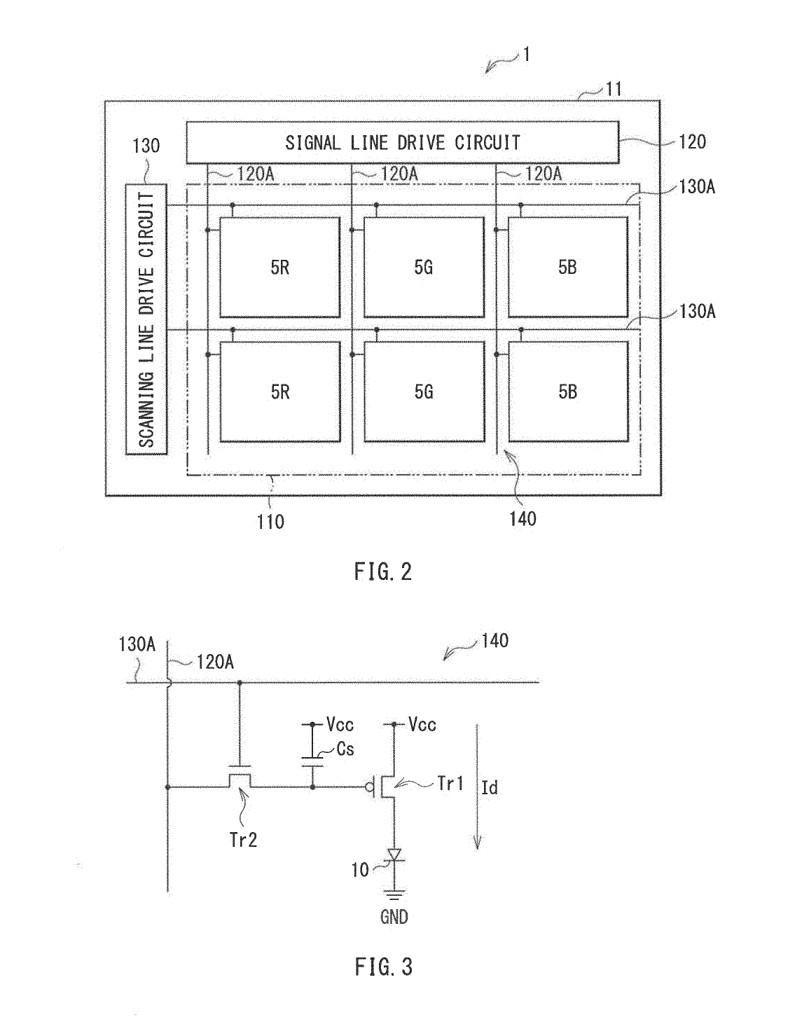

FIG. 2 illustrates the entire configuration of the display unit 1 including the display device 10 according to the present embodiment. The display unit 1 may be used as, for example, a mobile terminal apparatus such as a tablet and a smartphone. For example, the display unit 1 may include, as a display region 110, a plurality of display devices 10 that are arranged in matrix on the drive substrate 11. A signal line drive circuit 120 and a scanning line drive circuit 130 that are drivers for image display may be provided in periphery of the display region 110. Note that a combination of adjacent display devices 10 (subpixels 5R, 5G, and 5B) may configure one pixel.

A pixel drive circuit 140 may be provided in the display region 110. FIG. 3 illustrates an example of the pixel drive circuit 140. The pixel drive circuit 140 may be an active drive circuit provided on a lower layer of the anode 12. In other words, the pixel drive circuit 140 may include a drive transistor Tr1, a write transistor Tr2, a capacitor (a holding capacitor) Cs between the transistors Tr1 and Tr2, and the display device 10 that is coupled in series to the drive transistor Tr1 between a first power supply line (Vcc) and a second power supply line (GND). Each of the drive transistor Tr1 and the write transistor Tr2 may be configured by a common thin film transistor (TFT), and may have, for example, an inverted-staggered structure (so-called bottom gate type) or a staggered structure (so-called top gate type) without limitation.

In the pixel drive circuit 140, a plurality of signal lines 120A may be provided in a column direction, and a plurality of scanning lines 130A may be provided in a row direction. An intersection between each of the signal lines 120A and each of the scanning lines 130A may correspond to any one (subpixel) of the display devices 10. Each of the signal lines 120A may be coupled to the signal line drive circuit 120, and image signals may be supplied from the signal line drive circuit 120 to source electrodes of the respective write transistors Tr2 through the signal lines 120A. Each of the scanning lines 130A may be coupled to the scanning line drive circuit 130, and scanning signals may be sequentially supplied from the scanning line drive circuit 130 to gate electrodes of the respective write transistors Tr2 through the scanning lines 130A.

The display device 10 may have a structure in which the anode 12, the first light emitting unit 13, the second light emitting unit 14, and the cathode 15 are stacked in this order on the drive substrate 11 as described above. As illustrated in FIG. 4, the display device 10 may have a protective film 16 provided on the cathode 15. The display device 10 may be sealed by the drive substrate 11 and a sealing substrate 21 with a sealing layer 22 provided in between. In addition, a partition wall 23 may be provided between the display devices 10 adjacent to each other.

The drive substrate 11 may be a support. The display devices 10 may be arranged on one main surface of the drive substrate 11. The drive substrate 11 may be made of a known material such as quartz, glass, a metal foil, a resin film, and a resin sheet. Among them, quartz and glass may be preferable. When the drive substrate 11 is made of resin, examples of the resin may include methacrylate resins typified by polymethyl methacrylate (PMMA), polyesters such as polyethylene terephthalate (PET), polyethylene naphthalate (PEN), and polybutylene naphthalate (PBN), and a polycarbonate resin. It is necessary, however, for the drive substrate 11 to have a layered structure or to be subjected to a surface treatment in order to suppress water permeability and gas permeability.

The anode 12 may be preferably made of, for example, a metal, an alloy, an electrically conductive compound, and a mixture thereof, each having a large work function (for example, 4.0 eV or higher). Specific but non-limiting examples of the material of the anode 12 may include indium tin oxide (ITO), indium tin oxide containing silicon or silicon oxide, indium zinc oxide (IZO), tungsten oxide, and indium oxide containing zinc oxide. The specific but non-limiting examples of the material may further include gold (Au), platinum (Pt), nickel (Ni), tungsten (W), chromium (Cr), molybdenum (Mo), iron (Fe), cobalt (Co), copper (Cu), palladium (Pd), titanium (Ti), nitride of a metal material (for example, titanium nitride), molybdenum oxide, vanadium oxide, ruthenium oxide, tungsten oxide, manganese oxide, and titanium oxide. Note that, when a charge generation region is provided in contact with the anode 12, it is possible to select the material without considering the work function.

Note that, when a drive method of the display unit that is configured using the display device 10 is an active matrix method, the anode 12 may be patterned for each pixel, and may be coupled to an unillustrated driving thin film transistor provided on the drive substrate 11. In this case, the partition wall 23 may be provided on the anode 12, and a surface of the anode 12 in each of the subpixels 5R, 5G, and 5B may be exposed from an opening of the partition wall 23.

The partition wall 23 may be provided to secure an insulation property between the anode 12 and the cathode 15, and to form the light emitting region in a desired shape. Further, the partition wall 23 may have a function of a partition wall when application is performed by an inkjet method, a nozzle coating method, or other method in a manufacturing process. For example, the partition wall 23 may have an unillustrated upper partition wall on an unillustrated lower partition wall. The upper partition wall may be made of a photosensitive resin such as a positive photosensitive polybenzoxazole and a positive photosensitive polyimide. The lower partition wall may be made of an inorganic insulating material such as silicon dioxide (SiO₂). The opening corresponding to the light emitting region may be provided in the partition wall 23. An interval between the partition walls 23 adjacent to each other may be in a range, for example, from 3 μm to 20 μm or less. In particular, segmenting the display devices with an interval between the partition walls of 15 μm or less makes it possible to configure a display unit with higher definition (for example, an image resolution of 150 ppi or higher, more specifically, for example, 423 ppi). Note that the first light emitting unit 13, the second light emitting unit 14, and the cathode 15 may be provided not only on the opening but also on the partition wall 23; however, light emission occurs only on the opening of the partition wall 23.

The first light emitting unit 13 may include, for example, a hole injection layer 13A, a hole transport layer 13B, the light emitting layer 13C, an electron transport layer 13D, and an electron injection layer 13E that are stacked in order from the anode.

The hole injection layer 13A and the hole transport layer 13B may be buffer layers that enhance the efficiency of injecting holes to the light emitting layer 13C and prevent leakage. The sum of film thicknesses of the hole injection layer 13A and the hole transport layer 13B may be preferably in a range, for example, from 5 nm to 200 nm, and more preferably from 10 nm to 160 nm, depending on the entire configuration of the display device 10, in particular, the relationship with the electron transport layer 13D described later.

A material of each of the hole injection layer 13A and the hole transport layer 13B may be appropriately selected in relation with the materials of the electrodes (the anode 12 and the cathode 15) and adjacent layers, and the following materials may be used. Examples of the material may include benzine, styrylamine, triphenylamine, porphyrin, triphenylene, azatriphenylene, tetracyanoquinodimethane, triazole, imidazole, oxadiazole, polyarylalkane, phenylenediamine, arylamine, oxazole, anthracene, fluorenone, hydrazone, stilbene, and a derivative thereof, and heterocyclic conjugated monomers, oligomers, and polymers of polysilane compounds, vinyl carbazole compounds, thiophene compounds, and aniline compounds.

Specific but non-limiting examples of the material may include α-naphthyl phenylphenylene diamine, porphyrin, metal-tetraphenylporphyrin, metal-naphthalocyanine, hexacyanoazatriphenylene, 7,7,8,8-tetracyanoquinodimethane (TCNQ), F4-TCNQ, tetracyano-4,4,4-tris(3-methyl phenyl phenylamino)triphenylamine, N,N,N′,N′-tetrakis(p-tolyl)p-phenylenediamine, N,N,N′,N′-tetraphenyl-4,4′-diaminobiphenyl, N-phenylcarbazole, 4-di-p-tolylaminostilbene, poly(paraphenylenevinylene), poly(thiophenevinylene), and poly(2,2′-thienylpyrrole).

The light emitting layer 13C may be a region in which holes injected from the anode 12 and electrons injected from the electron transport layer 13D are recombined upon application of an electric field. The material that configures the light emitting layer 13C may preferably contain one or more of light emitting dopants and a host material, as with the light emitting layer 14C provided in the second light emitting unit 14 described above.

The electron transport layer 13D and the electron injection layer 13E may be provided to transport, to the light emitting layer 13C, electrons generated in the acceptor layer 14A. The electron transport layer 13D and the electron injection layer 13E may be stacked in this order from the anode 12. The electron transport layer 13D may preferably have a film thickness in a range, for example, from 10 nm to 50 nm, and more preferably from 5 nm to 20 nm, and the electron injection layer 13E may preferably have a film thickness of, for example, 5 nm or larger, depending on the entire configuration of the display device 10. Note that the electron transport layer 13D may not be necessarily provided and may be omitted.

As a material of the electron transport layer 13D, an organic material that has an excellent electron transport capacity and high contact characteristics with the acceptor layer 14A may be preferably used. Specific but non-limiting examples of the material may include an imidazole derivative and a phenanthroline derivative. This stabilizes supply of electrons to the light emitting layer 13C, thereby compensating stable driving with high efficiency for the emission color of high energy light emission.

Examples of the material of the electron injection layer 13E may include an alkali earth metal such as calcium (Ca) and barium (Ba), and an alkali metal such as lithium, sodium, and cesium. In addition, an oxide, a complex oxide, and a fluoride, for example, of these metals may be used singularly, or may be enhanced in stability as a mixture or an alloy thereof. In addition, the electron injection layer 13E may have a configuration similar to that of the above-described mixed layer 14D. This makes it possible to improve the efficiency of injecting electrons to the light emitting layer 13C.

The cathode 15 may be preferably made of a material having small work function (for example, lower than 4.0 eV). Note that one or both of the cathode 15 and the anode 12 may be preferably made of an electrically conductive material that allows visible light to pass therethrough. Examples of the electrically conductive material that allows visible light to pass therethrough may include indium oxide containing tungsten oxide, indium zinc oxide containing tungsten oxide, indium oxide containing titanium oxide, indium tin oxide containing titanium oxide, indium tin oxide, indium zinc oxide, and indium tin oxide added with silicon oxide. In addition, a material that allows light to pass therethrough may be used, and for example, a metal film having a thickness in a range from about 5 nm to about 30 nm may be used.

The protective film 16 may have a thickness in a range, for example, from 2 μm to 3 μm, and may be made of any of an insulating material and an electrically conductive material. As the insulating material, an inorganic amorphous insulating material such as amorphous silicon (α-Si), amorphous silicon carbide (α-SiC), amorphous silicon nitride (α-Si₁₋ₓNₓ), and amorphous carbon (α-C) may be preferable. Such an inorganic amorphous insulating material may have low water permeability because the material does not configure a grain, thereby forming a preferable protective film.

The counter substrate 21 may be located on the display device 10 on cathode 15 side, and may seal the display device 10, together with the sealing layer 22 that is made of, for example, a thermosetting resin or an ultraviolet curable resin. The counter substrate 21 may be made of a material such as glass that is transparent to light generated in the display device 10. For example, a color filter 21A and a black matrix 21B may be provided in the counter substrate 21. The counter substrate 21 may extract the light generated in the display device 10, and absorb external light that is reflected by wiring lines between the display devices 10, thereby improving a contrast.

The color filter 21A may include, for example, a red filter, a green filter, and a blue filter that are disposed in order. The red filter, the green filter, and the blue filter may be each formed in, for example, a rectangular shape, and be provided without gap. Each of the red filter, the green filter, and the blue filter may be made of a resin mixed with a pigment, and may be adjusted through selection of the pigment such that light transmittance in a target wavelength range of red, green, or blue becomes high whereas light transmittance in other wavelength ranges becomes low. Note that a color filter corresponding to any of the subpixels 5R, 5G, and 5B on which the display device 10 is formed may be provided in each display device 10.

The black matrix 21B may be configured by, for example, a black resin film that is mixed with a black colorant and has optical density of 1 or higher, or a thin film filter using interference of a thin film. Among them, the black resin film may be preferably used because the black matrix 21B is easily formed at low cost. The thin film filter may be formed by, for example, stacking one or more thin films each made of metal, metal nitride, or metal oxide, and may attenuate light with use of interference of the thin films. Specific but non-limiting examples of the thin film filter may be a filter in which Cr and chromium(III) oxide (Cr₂O₃) are alternately stacked.

The layers from the anode 12 to the cathode 15 configuring the display device 10 may be each formed through, for example, a dry process such as a vacuum deposition method, an ion beam method (an EB method), a molecular beam epitaxy method (an MBE method), a sputtering method, and an organic vapor phase deposition (OVPD) method.

Further, the first light emitting unit 13 and the second light emitting unit 14 may be each formed through, in addition to the above-described methods, a wet process, for example, a coating method such as a laser transfer method, a spin coating method, a dipping method, a doctor blade method, a discharge coating method, and a spray coating method, and a printing method such as an inkjet method, an offset printing method, a letterpress printing method, an intaglio printing method, a screen printing method, and a micro gravure coating method. The dry process and the wet process may be used together depending on the property of each of the first light emitting unit 13, the second light emitting unit 14, and other members.

In the display unit 1, the scanning signal may be supplied from the scanning line drive circuit 130 to each of the subpixels 5R, 5G, and 5B through the gate electrode of the write transistor Tr2, and the image signal may be supplied from the signal line drive circuit 120 through the write transistor Tr2 to the holding capacitor Cs, and may be held in the holding capacitor Cs. In other words, the drive transistor Tr1 may be ON/OFF controlled in response to the signal held in the holding capacitor Cs, which may cause a drive current Id to be injected into the display device 10. As a result, holes and electrons may be recombined to emit light. The light may pass through the anode 12 and the drive substrate 11 in the case of a bottom surface emission (bottom emission), and pass through the cathode 15, the color filter 21A, and the counter substrate 21 in the case of the top surface emission (top emission), thus allowing the light to be extracted.

As described above, in addition to high light-emitting efficiency and long lifetime, high-definition light emission has been demanded for the display unit using the organic electroluminescent device in recent years. Typically, when a large current flows through the organic electroluminescent device, deterioration is accelerated and lifetime is reduced. Therefore, a tandem device in which a plurality of light emitting units are stacked has been developed as an organic electroluminescent device that provides high luminance with a small current. In the tandem device, typically, a plurality of layers including a light emitting layer are stacked with a layer having high electrical conductivity as a middle layer. Therefore, a layer having high electrical conductivity and a layer having a low electrical conductivity are mixedly provided between the anode and the cathode in the structure.

In a case where the tandem devices are disposed adjacent to one another, when a layer having high electrical conductivity is provided in an adjacent tandem device, a crosstalk phenomenon in which a current is leaked through the layer having high electrical conductivity (for example, the middle layer) may occur. As a result of the crosstalk phenomenon, a tandem device adjacent to a specified tandem device may also emit light, which may deteriorate display quality. It is possible to suppress occurrence of the crosstalk phenomenon by, for example, providing a structural object between the tandem devices adjacent to each other, for example, providing a recess or a protrusion on a partition wall between the tandem devices adjacent to each other, or providing, around the anode, a metal wiring line electrically coupled to the light emitting unit. In a high-definition display, however, layout of the pixels may be limited, and providing the structural object between the tandem devices adjacent to each other, namely, between the pixels may inhibit high definition. In addition, decrease in the pixel opening may reduce luminance, and applying a higher current in order to improve luminance may reduce lifetime of the organic electroluminescent device.

In contrast, in the present embodiment, the display device 10 has the tandem structure, in which the first light emitting unit 13 and the second light emitting unit 14 are provided. The second light emitting unit 14, among the two light emitting units, that is not in contact with the anode 12 may have the four-layer structure of the acceptor layer 14A, the donor layer 14B, the light emitting layer 14C, and the mixed layer 14D. Among the four layers, the acceptor layer 14A may be made of, for example, hexaazatriphenylene; the donor layer 14B may be made of, for example, an aromatic tertiary amine compound; and the mixed layer 14D may be made of one of an alkali metal and an alkali earth metal, and a heterocyclic compound. This improves electrical conductivity of each of the layers configuring the second light emitting unit 14. In other words, the efficiency of injecting holes and electrons to the light emitting layer 14C, in particular, the efficiency of injecting holes from the acceptor layer 14A and the donor layer 14B to the light emitting layer 14C is improved, which suppresses inflow (leakage) of charges to the adjacent display device, namely, suppresses occurrence of the crosstalk phenomenon.

As described above, in the display device 10 and the display unit 1 according to the present embodiment, the first light emitting unit 13 and the second light emitting unit 14 are stacked between the anode 12 and the cathode 15 that face each other. The second light emitting unit 14, among them, that is not in contact with the anode 12 has the four-layer structure in which the acceptor layer 14A, the donor layer 14B, the light emitting layer 14C, and the mixed layer 14D are stacked in order from the anode 12. This makes it possible to improve movement of charges to the light emitting layer 14C, in particular, the injection efficiency of holes in the second light emitting unit 14, thereby suppressing the crosstalk phenomenon. In other words, it is possible to provide the high-definition display unit and the high-definition electronic apparatus each having high light-emitting efficiency.

Note that, in the present embodiment, the display device 10 has the structure in which the two light emitting units (the first light emitting unit 13 and the second light emitting unit 14) are stacked between the anode 12 and the cathode 15; however, the structure is not limited thereto. For example, as with display devices fabricated in Examples described later, three light emitting units, namely, a third light emitting unit in addition to the first light emitting unit and the second light emitting unit may be provided between the anode 12 and the cathode 15. In this case, the light emitting unit that is not in direct contact with the anode 12, namely, the third light emitting unit may preferably have a structure similar to the structure of the second light emitting unit 14 according to the present embodiment.

### 2. Application Examples

Application examples of the display unit 1 including the display device 10 described in the above-described embodiment are described below. The display unit according to the above-described embodiment may be applicable to a display unit of an electronic apparatus in various field that displays, as an image, an image signal outputted from outside or an image signal generated inside, such as a television, a digital camera, a notebook personal computer, a mobile terminal apparatus such as a mobile phone, and a video camera. In particular, the display unit according to the above-described embodiment may be suitable for a mid-sized to small-sized display for mobile apparatuses. Examples thereof are described below.

### [Module]

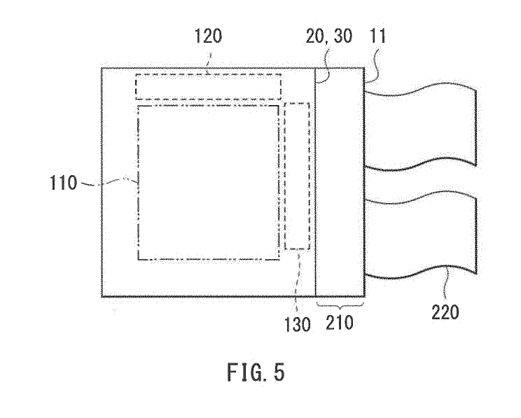

The display unit 1 including the display device 10 according to the above-described embodiment may be incorporated, as a module illustrated in FIG. 5, into various electronic apparatuses such as application examples 1 and 2 described later. For example, the module may include, on a side of the drive substrate 11, a region 210 that is exposed from the protective film 16 and the counter substrate 21. Unillustrated external coupling terminals that are extended wiring lines from the signal line drive circuit 120 and the scanning line drive circuit 130 may be provided in the exposed region 210. A flexible printed circuit (FPC) 220 for input and output of signals may be provided in the external coupling terminals.

### Application Example 1

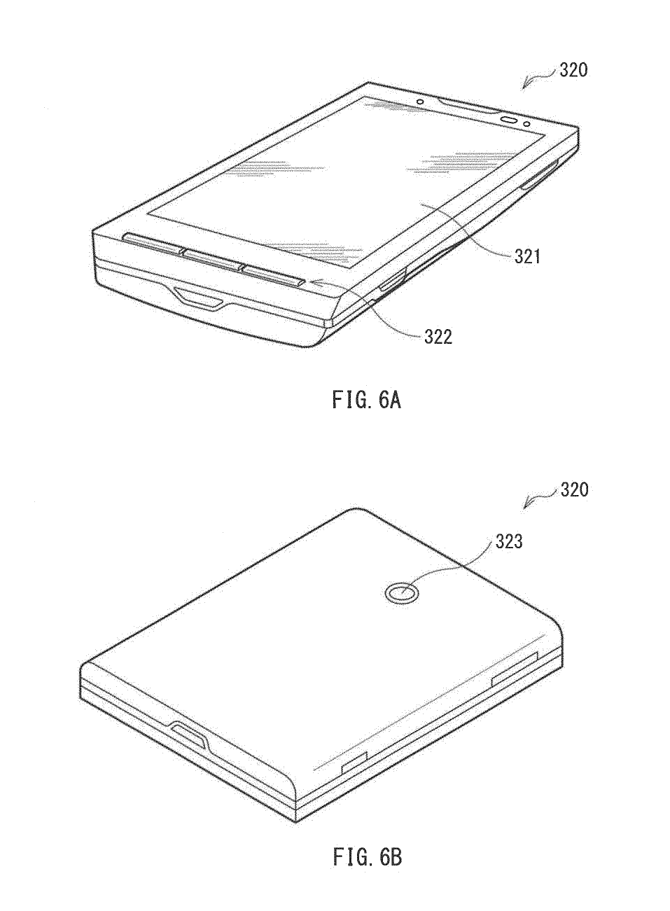

FIG. 6A and FIG. 6B each illustrate an appearance of a smartphone 320 according to Application Example 1. The smartphone 320 may include, for example, a display section 321 and an operation section 322 on front side, and a camera 323 on rear side. The display unit 1 according to the above-described embodiment may be mounted on the display section 321.

### Application Example 2

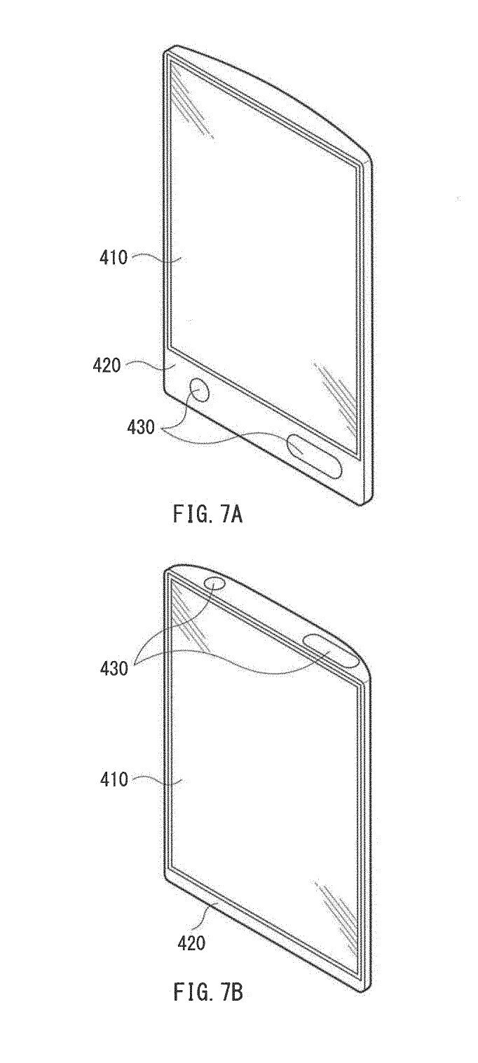

FIG. 7A and FIG. 7B each illustrate an appearance of a tablet personal computer according to Application Example 2. The tablet personal computer may include, for example, a housing (a non-display section) 420 on which a display section 410 and an operation section 430 are disposed. The display unit 1 according to the above-described embodiment may be mounted on the display section 410.

### 3. Examples

### Example 1

Next, Examples of the technology are described. As samples (Examples 1 to 5 and comparative examples 1 to 4), a VGA display panel having definition (resolution) of 640×480 pixels and an FHD display panel having definition (resolution) of 1920×1080 pixels were fabricated. The structure of each of the display panels are as follows.

The VGA display panel included a plurality of pixels with a resolution of 148 ppi in a region, the diagonal length of which was 5.2 inches. Each of the pixels included, as subpixels, a red pixel (5R), a green pixel (5G), and a blue pixel (5B). The subpixels each had a substantially rectangular shape, and were arranged in matrix with an interval of 55 μm in a row direction and 165 μm in a column direction. The partition wall 23 was provided between the subpixels adjacent to each other, and the width in the row direction and the width in the column direction of the partition wall 23 were both 25 μm. Note that an aperture ratio of each of the subpixels was set to 45%.

The FHD display panel included a plurality of pixels with a resolution of 423 ppi in a region, the diagonal length of which was 5.2 inches. Each of the pixels included, as subpixels, a red pixel (5R), a green pixel (5G), and a blue pixel (5B). The subpixels each had a substantially rectangular shape, and were arranged in matrix with an interval of 20 μm in a row direction and 60 μm in a column direction. The partition wall 23 was provided between the subpixels adjacent to each other, and the width in the row direction and the width in the column direction of the partition wall 23 were both 9 μm. Note that an aperture ratio of each of the subpixels was set to 45%.

The light emitting device 10 in each of the subpixels was formed in the following manner. First, as the anode 12, an Al film having a film thickness of 200 nm and an ITO film having a film thickness of 20 nm were formed in this order. Next, the first light emitting unit 13 was formed on the anode 12. As the hole injection layer 13A, a film of hexanitrile aza-triphenylene represented by the formula (7) was first formed with a film thickness of 10 nm through a vacuum deposition method. Thereafter, as the hole transport layer 13B, a film of α-NPD represented by the formula (8) was formed with a film thickness of 120 nm through the vacuum deposition method.

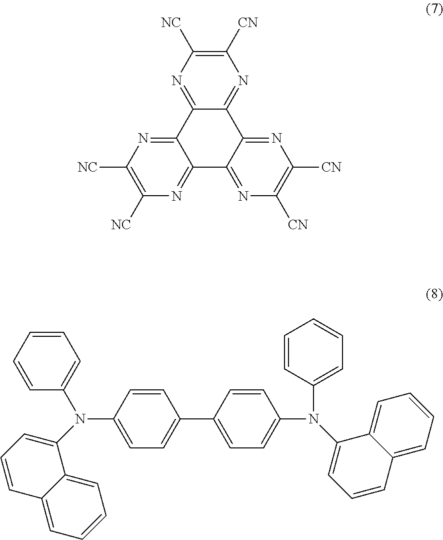 [SMILES: N#Cc1nc2c3nc(C#N)c(C#N)nc3c3nc(C#N)c(C#N)nc3c2nc1C#N ; c1ccc(N(c2ccc(-c3ccc(N(c4ccccc4)c4cccc5ccccc45)cc3)cc2)c2cccc3ccccc23)cc1]

Thereafter, the light emitting layer 13C that uses the compound represented by the formula (9) as a host material and a compound represented by the formula (10) as a dopant was so formed with a total film thickness of 30 nm through the vacuum deposition method as to be 5% in a film thickness ratio. Note that the light emitting layer 13C was formed as a blue light emitting layer.

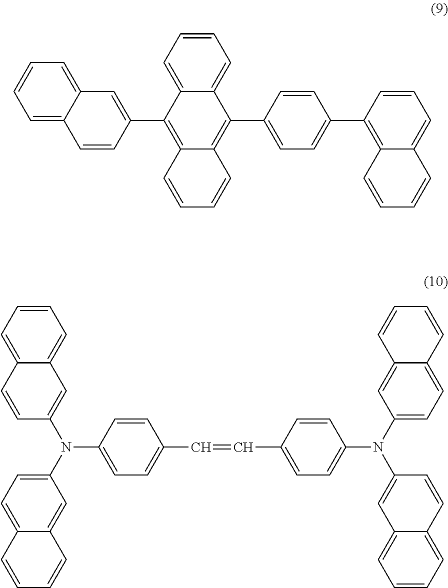

Subsequently, as the electron transport layer 13D, the compound represented by the formula (11) was formed with a film thickness of 20 nm through the vacuum deposition method. Thereafter, as the electron injection layer 13E, a film of bathocuproine (BCP) represented by the formula (6-11) and Li was formed with a film thickness of 10 nm through the vacuum deposition method such that the weight ratio of BCP and Li became 96:4.

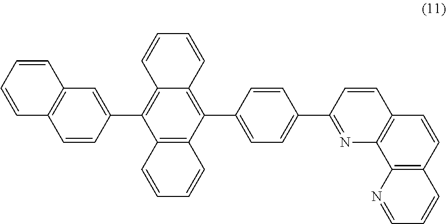 [SMILES: c1ccc2cc(-c3c4ccccc4c(-c4ccc(-c5ccc6ccc7cccnc7c6n5)cc4)c4ccccc34)ccc2c1]

Next, the second light emitting unit 14 was formed. As the acceptor layer 14A, a film of hexanitrile aza-triphenylene represented by the formula (7) was formed with a film thickness of 5 nm through the vacuum deposition method. Thereafter, as the donor layer 14B, a film of α-NPD represented by the formula (8) was formed with a film thickness of 30 nm through the vacuum deposition method. Subsequently, as the light emitting layer 14C, a film of a host and a dopant was formed with a film thickness of 30 nm at 5% in a film thickness ratio. The host was obtained by mixing the compound represented by the formula (4-4) as the hole transport host material and the compound represented by the formula (5-3) as the electron transport host material at 1:1. The dopant was Ir(bzp)₃ represented by the formula (12). Note that the light emitting layer (the light emitting layer 14C) of the second light emitting unit 14 was formed as a yellow light emitting layer.

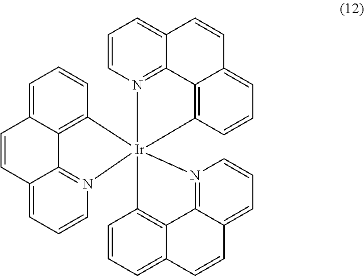

Next, as the mixed layer 14D, a film of BCP represented by the formula (6-10) and Li was formed with a film thickness of 30 nm through the vacuum deposition method such that the weight ratio of BCP and Li became 96:4. Subsequently, as the cathode 15, a film of indium zinc oxide (IZO) was formed with a film thickness of 160 nm through the vacuum deposition method. The display device 10 (Example 1) was fabricated in the above-described manner.

In Example 2 and Comparative Example 3, the third light emitting unit was further provided on the second light emitting unit. Table 1 shows materials used for the respective layers configuring the third light emitting unit. Note that the light emitting layer of the third light emitting unit was made of the host that was obtained by mixing the compounds respectively represented by the formulae (4-4) and (5-2) at 1:1, and the compound represented by the formula (13) as the dopant. The light emitting layer was formed as a red light emitting layer. The display devices were fabricated with use of a method similar to the method of Example 1 described above, except for the structures summarized in Table 1 that includes the light emitting layers in Example 2 and Comparative Example 3 and layers in Examples 3 to 5 and comparative examples 1, 2, and 4.

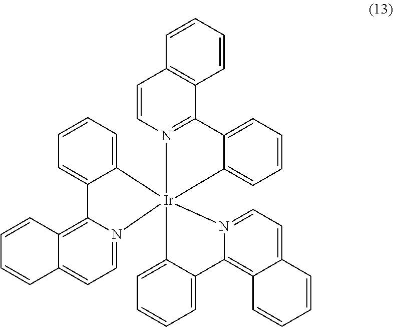

As for the fabricated display devices 10 (Examples 1 to 5 and Comparative Examples 1 to 4), color coordinates in each RGB pixel at current density of 0.1 mA/cm² and 10 mA/cm² were measured to calculate NTSC ratio (u′v′) for each display panel. Table 1 shows a list of film thicknesses of the respective layers configuring the second light emitting unit (and the third light emitting unit) according to Examples 1 to 5 and Comparative Examples 1 to 3. Table 2 summarizes the NTSC ratios at the current density of 0.1 mA/cm² and 10 mA/cm² according to Examples 1 to 5 and Comparative Examples 1 to 3.

TABLE 1

| Second Light Emitting Unit | | | | | Third Light Emitting Unit | | | |
|---|---|---|---|---|---|---|---|---|
| Acceptor | | Yellow | | | Acceptor | | Red | |
| Layer | | Light | Mixed Layer | | Layer | | Light | |
| Hole | Donor Layer | Emitting | Electron | Electron | Hole | Donor Layer | Emitting | |
| Injection | Hole Transport | Layer | Transport | Injection | Injection | Hole Transport | Layer | Mixed |
| Layer | Layer | Dopant | Layer | Layer | Layer | Layer | Dopant | Layer |

| Example 1 | Formula | Formula (8) | | Formula | Formula (6-10) + Li | — | — | — | — |
|---|---|---|---|---|---|---|---|---|---|
| | (7) | | | (12) | | | | | |
| | 5 nm | 30 nm | | 20 nm | 30 nm | — | — | — | — |
| Example 2 | Formula | Formula (8) | | Formula | Formula (6-10) + Li | Formula | Formula (8) | Formula | Formula |
| | (7) | | | (12) | | (7) | | (13) | (6-10) + |
| | | | | | | | | | Li |
| | 5 nm | 30 nm | | 20 nm | 10 nm | 5 nm | 30 nm | 20 nm | 30 nm |
| Example 3 | Formula | Formula (8) | | Formula | Formula (6-10) + Li | — | — | — | — |
| | (2-1) | | | (12) | | | | | |
| | 5 nm | 30 nm | | 20 nm | 30 nm | — | — | — | — |
| Example 4 | Formula | Formula (3-6) | | Formula | Formula (6-10) + Li | — | — | — | — |
| | (2-1) | | | (12) | | | | | |
| | 5 nm | 30 nm | | 20 nm | 30 nm | — | — | — | — |
| Example 5 | Formula | Formula (6-5) | | Formula | Formula (6-3) | — | — | — | — |
| | (7) | | | (12) | | | | | |
| | 5 nm | 30 nm | | 20 nm | 30 nm | — | — | — | — |
| Comparative | Formula | Formula | Formula | Formula | Formula (6-10) + Li | — | — | — | — |
| Example 1 | (7) | (8) | (6-10) | (12) | | | | | |
| | 5 nm | 10 nm | 20 nm | 20 nm | 30 nm | — | — | — | — |

| | | | | | | | | | |
|---|---|---|---|---|---|---|---|---|---|
| Comparative | Formula | Formula (8) | Formula | Formula | Formula | — | — | — | — |
| Example 2 | (7) | | (12) | (11) | (6-10) + | | | | |
| | | | | | Li | | | | |
| | 5 nm | 30 nm | 20 nm | 20 nm | 10 nm | — | — | — | — |

| | | | | | | | | | |
|---|---|---|---|---|---|---|---|---|---|
| Comparative | Formula | Formula (8) | Formula | Formula (6-10) + Li | Formula | Formula | Formula | Formula | Formula |
| Example 3 | (7) | | (12) | | (7) | (8) | (6-10) | (13) | (6-10) + Li |
| | 5 nm | 30 nm | 20 nm | 10 nm | 5 nm | 30 nm | 20 nm | 20 nm | 30 nm |
| Comparative | Formula | Formula (8) | Formula | Formula (6-10) + Li | — | — | | — | — |
| Example 4 | (7) | | (12) | | | | | | |
| | 5 nm | 30 nm | 45 nm | 5 nm | — | — | | — | — |

TABLE 2

| | 148 ppi | | 423 ppi | |
|---|---|---|---|---|
| | 0.1 mA/cm² | 10 mA/cm² | 0.1 mA/cm² | 10 mA/cm² |
| Example 1 | 111% | 112% | 111% | 112% |
| Example 2 | 130% | 130% | 129% | 130% |
| Example 3 | 112% | 112% | 111% | 112% |
| Example 4 | 112% | 112% | 110% | 112% |
| Example 5 | 112% | 113% | 110% | 113% |
| Comparative | 74% | 112% | 50% | 112% |
| Example 1 | | | | |
| Comparative | 65% | 112% | 60% | 112% |
| Example 2 | | | | |
| Comparative | 60% | 130% | 52% | 130% |
| Example 3 | | | | |
| Comparative | 85% | 112% | 60% | 112% |
| Example 4 | | | | |

In the display devices 10 according to the embodiments of Examples 1 to 5 of the disclosure, the second light emitting unit 14 on cathode 15 side had the four-layer structure. In the four-layer structure, the donor layer 14B that was a donor of the acceptor material was provided directly on the acceptor layer 14A that was made of the acceptor material. This resulted in generation of a sufficient amount of charges (holes). In addition, by forming the light emitting layer 14C into a thin film with use of a mixed host that contained a hole transporting host material and an electron transporting host material, it became possible to sufficiently transport charges. Further, the mixed layer 14D provided on the light emitting layer 14C contained a heterocyclic compound as a host and, for example, Li metal, which caused charge (electron) movement between the heterocyclic compound and the Li metal. In other words, the second light emitting unit 14 (and the third light emitting unit) was configured by the layers each having high electrical conductivity. The second light emitting unit 14 (and the third light emitting unit) did not include a layer having low electrical conductivity as described above, which is presumed to have suppressed occurrence of crosstalk on cathode 15 side. In addition, as can be seen from Table 2, in the NTSC ratio of each of Examples 1 to 5, the constant color gamut was ensured from low luminance to high luminance irrespective of the current density. This was because charges were sufficiently supplied to the first light emitting unit 13 and the second light emitting unit 14.

In contrast, in each of Comparative Examples 1 to 4, the NTSC ratio was lower than the NTSC ratio of each of Examples 1 to 5. The tendency was high, particularly, at low current density. This was because the layer made of the electron transporting material or BCP with low electrical conductivity not involved with charge generation was stacked in the second light emitting unit (or the third light emitting unit), which caused large difference in electrical conductivity between layers. This might cause crosstalk to increase color mixing. In particular, when the resolution was increased to 423 ppi, the color gamut on low luminance side (on the cathode side) was decreased.

Although the technology has been described with reference to the embodiment and Examples, the technology is not limited to the embodiment and Examples, and may be modified in a wide variety of ways.

For example, the active matrix display unit using the TFT substrate has been described in the above-described embodiment and Examples; however, the display unit is not limited thereto and may be a passive display unit. In addition, the configuration of the pixel drive circuit for the active matrix driving is not limited to the configuration described above in the embodiment, and a capacitor and a transistor may be added as necessary. In this case, necessary drive circuits may be added in addition to the above-described signal line drive circuit 120 and the above-described scanning line drive circuit 130, depending on modification of the pixel drive circuit.

Further, the top emission display device in which light is extracted from side of cathode 15 provided opposite to the substrate 11 has been described in the above-described embodiment and Examples. The technology, however, may be applied to a bottom emission display device when the substrate 11 is made of a transparent material. In this case, the display device may have a layered structure in which the layers are stacked inversely from the layered structure of the display device 10 illustrated in FIG. 1. Alternatively, the same structure may be provided on a transparent electrode that is provided on a transparent substrate.

In addition, the configuration of the display device 10 has been specifically described in the above-described embodiment and Examples; however, all of the layers may not be necessarily provided. In addition, the display device 10 may further include other layers. For example, the hole transport layer 13B may not be provided on the hole injection layer 13A; instead the light emitting layer 13C may be provided directly on the hole injection layer 13A.

Note that the effects described herein are mere examples. The effect of the technology is not limited thereto, and may include other effects.

Note that the technology may also have the following configurations.

(1)

A display device, including:

an anode;

a cathode that faces the anode;

a first light emitting unit provided on the anode, the first light emitting unit including at least a first light emitting layer; and

a second light emitting unit provided on the cathode, the second light emitting unit including at least a second light emitting layer, the second light emitting unit having a four-layer structure in which an acceptor layer, a donor layer, the second light emitting layer, and a mixed layer are stacked in order from the first light emitting unit, the donor layer containing one or more of aromatic tertiary amines, and the mixed layer containing one or more of alkali metals and alkali earth metals and one or more of heterocyclic compounds.

(2)

The display device according to (1), wherein the first light emitting layer emits light of a color that is different from a color of light emitted from the second light emitting layer.

(3)

The display device according to (1) or (2), wherein the second light emitting layer contains a phosphorescent material.

(4)

The display device according to any one of (1) to (3), wherein the second light emitting layer contains a hole transporting host material and an electron transporting host material.

(5)

The display device according to any one of (1) to (4), wherein the second light emitting layer has a film thickness of 30 nm or less.

(6)

The display device according to any one of (1) to (5), wherein the acceptor layer contains one or more of a hexaazatriphenylene derivative, a fluorinated derivative of cyano benzoquinone dimethane, and radialenes.

(7)

A display unit provided with a plurality of display devices, each of the display devices including:

an anode;

a cathode that faces the anode;

a first light emitting unit provided on the anode, the first light emitting unit including at least a first light emitting layer; and

a second light emitting unit provided on the cathode, the second light emitting unit including at least a second light emitting layer, the second light emitting unit having a four-layer structure in which an acceptor layer, a donor layer, the second light emitting layer, and a mixed layer are stacked in order from the first light emitting unit, the donor layer containing one or more of aromatic tertiary amines, and the mixed layer containing one or more of alkali metals and alkali earth metals and one or more of heterocyclic compounds.

(8)

The display unit according to (7), wherein the display unit has a screen resolution of 150 ppi or larger.

(9)

An electronic apparatus provided with a display unit, the display unit including a plurality of display devices in a display section, each of the display devices including:

an anode;

a cathode that faces the anode;

a first light emitting unit provided on the anode, the first light emitting unit including at least a first light emitting layer; and

a second light emitting unit provided on the cathode, the second light emitting unit including at least a second light emitting layer, the second light emitting unit having a four-layer structure in which an acceptor layer, a donor layer, the second light emitting layer, and a mixed layer are stacked in order from the first light emitting unit, the donor layer containing one or more of aromatic tertiary amines, and the mixed layer containing one or more of alkali metals and alkali earth metals and one or more of heterocyclic compounds.

In the display device, the display unit, and the electronic apparatus according to the respective embodiments of the technology, the first light emitting unit and the second light emitting unit are stacked between the anode and the cathode that face each other. The second light emitting unit, out of the first light emitting unit and the second light emitting unit, that is provided on the cathode has the four-layer structure. In the four-layer structure, the acceptor layer, the donor layer, the second light emitting layer, and the mixed layer are provided in this order from the first light emitting unit. The donor layer contains one or more of aromatic tertiary amines. The mixed layer contains one or more of alkali metals and alkali earth metals and one or more of heterocyclic compounds. The four-layer structure improves movement of charges in the second light emitting unit, more specifically movement of holes and electrons to the second light emitting layer.

According to the display device, the display unit, and the electronic apparatus of the respective embodiments of the technology, the first light emitting unit and the second light emitting unit are stacked between the anode and the cathode that face each other. The second light emitting unit, out of the first light emitting unit and the second light emitting unit, that is provided on the cathode has the four-layer structure. In the four-layer structure, the acceptor layer, the donor layer, the second light emitting layer, and the mixed layer are provided in order from the first light emitting unit. The donor layer contains one or more of aromatic tertiary amines. The mixed layer contains one or more of alkali metals and alkali earth metals and one or more of heterocyclic compounds. This improves movement of holes and electrons to the second light emitting layer in the second light emitting unit. Accordingly, it is possible to provide the display device that suppresses the crosstalk phenomenon and has improved light-emitting efficiency, as well as the high-definition display unit and the high-definition electronic apparatus. Note that the effects described herein are not limited to those described above, and may be any effects described in the present disclosure.

It should be understood by those skilled in the art that various modifications, combinations, sub-combinations, and alterations may occur depending on design requirements and other factors insofar as they are within the scope of the appended claims or the equivalents thereof.

What is claimed is:

1. A display device, comprising:
an anode;
a cathode that faces the anode;
a first light emitting unit provided on the anode, the first light emitting unit including at least a first light emitting layer; and
a second light emitting unit provided on the cathode, the second light emitting unit including at least a second light emitting layer, the second light emitting unit having a four-layer structure in which an acceptor layer, a donor layer, the second light emitting layer, and a mixed layer are stacked in order from the first light emitting unit, the donor layer containing one or more of aromatic tertiary amines, and the mixed layer containing one or more of alkali metals and alkali earth metals and one or more of heterocyclic compounds.

2. The display device according to claim 1, wherein the first light emitting layer emits light of a color that is different from a color of light emitted from the second light emitting layer.

3. The display device according to claim 1, wherein the second light emitting layer contains a phosphorescent material.

4. The display device according to claim 1, wherein the second light emitting layer contains a hole transporting host material and an electron transporting host material.

5. The display device according to claim 1, wherein the second light emitting layer has a film thickness of 30 nm or less.

6. The display device according to claim 1, wherein the acceptor layer contains one or more of a hexaazatriphenylene derivative, a fluorinated derivative of cyano benzoquinone dimethane, and radialenes.

7. A display unit provided with a plurality of display devices, each of the display devices comprising:
an anode;
a cathode that faces the anode;
a first light emitting unit provided on the anode, the first light emitting unit including at least a first light emitting layer; and
a second light emitting unit provided on the cathode, the second light emitting unit including at least a second light emitting layer, the second light emitting unit having a four-layer structure in which an acceptor layer, a donor layer, the second light emitting layer, and a mixed layer are stacked in order from the first light emitting unit, the donor layer containing one or more of aromatic tertiary amines, and the mixed layer containing one or more of alkali metals and alkali earth metals and one or more of heterocyclic compounds.

8. The display unit according to claim 7, wherein the display unit has a screen resolution of 150 ppi or larger.

9. An electronic apparatus provided with a display unit, the display unit including a plurality of display devices in a display section, each of the display devices comprising:
an anode;
a cathode that faces the anode;
a first light emitting unit provided on the anode, the first light emitting unit including at least a first light emitting layer; and
a second light emitting unit provided on the cathode, the second light emitting unit including at least a second light emitting layer, the second light emitting unit having a four-layer structure in which an acceptor layer, a donor layer, the second light emitting layer, and a mixed layer are stacked in order from the first light emitting unit, the donor layer containing one or more of aromatic tertiary amines, and the mixed layer containing one or more of alkali metals and alkali earth metals and one or more of heterocyclic compounds.
